(19) United States
(12) Patent Application Publication
(10) Pub. No.: US 2026/0113932 A1
(43) Pub. Date: Apr. 23, 2026

(54) SEMICONDUCTOR DEVICES AND METHODS OF MAKING SEMICONDUCTOR DEVICES

(71) Applicant: Taiwan Semiconductor Manufacturing Company, Ltd., Hsinchu (TW)

(72) Inventors: Kai-Ping HUANG, Hsinchu (TW); Siauun ONG, Hsinchu (TW); Shang-Hsian SHEN, Hsinchu (TW); Chia-En HUANG, Hsinchu (TW); Kuan-Lun CHENG, Hsinchu (TW)

(73) Assignee: Taiwan Semiconductor Manufacturing Company, Ltd., Hsinchu (TW)

(21) Appl. No.: 18/924,429

(22) Filed: Oct. 23, 2024

(51) Int. Cl. H10B 20/25

(52) U.S. Cl. CPC H10B 20/25

(57) ABSTRACT

A semiconductor device includes gate lines intersecting an active region, and a gate dielectric layer formed between the active region and the gate lines and that is configured to function as anti-fuse structure. A method of manufacturing a semiconductor device includes forming an active region and a plurality of gates intersecting the active region, and forming a gate dielectric material configured to function as an anti-fuse structure between the active region and the gates.

### BACKGROUND

The semiconductor device manufacturing industry has experienced exponential growth. Over time, technological advances in materials, design, and fabrication have produced semiconductor devices with progressively smaller and more complex circuits. During the evolution of semiconductor devices, the number of interconnected devices per chip area has generally increased while the dimensions of circuit components have generally decreased. This scaling-down of semiconductor device architecture generally increases the complexity of processing and manufacturing semiconductor devices.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a computing system according to embodiments of the disclosure.

FIG. 2A shows an anti-fuse array according to embodiments of the disclosure.

FIG. 2B shows an anti-fuse array according to embodiments of the disclosure.

FIG. 2C shows an anti-fuse array according to embodiments of the disclosure.

FIGS. 3, 4A, and 4B show operations of the anti-fuse array shown in FIG. 2B.

FIG. 5 shows a plan view of a semiconductor device according to embodiments of the disclosure.

FIG. 6 shows a perspective view of a portion of the semiconductor device shown in FIG. 5.

FIGS. 7A, 7A′, 7A″, and 7B show cross-sections of portions of the semiconductor device shown in FIG. 5.

FIGS. 7C and 7D show cross-sections of portions of an anti-fuse structure according to embodiments of the disclosure.

FIG. 7E shows a cross-section of a semiconductor device according to embodiments of the disclosure.

FIG. 8 shows a plan view of a semiconductor device according to embodiments of the disclosure.

FIG. 9 shows a perspective view of a portion of the semiconductor device shown in FIG. 8.

FIG. 10A shows a cross-section of a portion of the semiconductor device shown in FIG. 8.

FIG. 10B shows a cross-section of a portion of a semiconductor device according to embodiments of the disclosure.

FIG. 11 shows a plan view of a semiconductor device according to embodiments of the disclosure.

FIG. 12 shows a perspective view of a portion of the semiconductor device shown in FIG. 11.

FIGS. 13A, 13A′, 13A″, 13B, 13C, and 13D show cross-sections of portions of the semiconductor device shown in FIG. 11.

FIG. 13E illustrates a cross-section of a portion of a semiconductor device according to an embodiment of the disclosure.

FIG. 14A shows an anti-fuse array according to embodiments of the disclosure.

FIG. 14B shows an anti-fuse array according to embodiments of the disclosure.

FIG. 14C shows an anti-fuse array according to embodiments of the disclosure.

FIGS. 14D, 14E, and 14F show operations of the anti-fuse array shown in FIG. 14B.

FIG. 15 shows a plan view of a semiconductor device according to an embodiment of the disclosure.

FIG. 16 shows a perspective view of a portion of the semiconductor device shown in FIG. 15.

FIG. 17 shows a cross-section of a portion of the semiconductor device shown in FIG. 15.

FIG. 18A shows an anti-fuse array according to embodiments of the disclosure.

FIG. 18B shows an anti-fuse array according to embodiments of the disclosure.

FIG. 18C shows an anti-fuse array according to embodiments of the disclosure.

FIGS. 18D, 18E, and 18F show operations of the anti-fuse array shown in FIG. 18B.

FIG. 19A shows a plan view of a semiconductor device according to embodiments of the disclosure.

FIG. 19B shows a plan view of a semiconductor device according to embodiments of the disclosure.

FIG. 19C shows a plan view of a semiconductor device according to embodiments of the disclosure.

FIG. 20 shows a perspective view of a portion of the semiconductor device shown in FIGS. 19A, 19B, and 19C.

FIGS. 21A, 21B, 21C, 22, and 23 show cross-sections of portions of semiconductor devices according to embodiments of the disclosure.

FIG. 24 is a flow chart of a method of manufacturing a semiconductor device according to an embodiment of the disclosure.

FIGS. 25A, 25B, 25C, 25D, 25E, 25F, 25G, 25H, 25I, 25J, 25K, 25L, 25M, 25N, 25O show cross-section views of sequential process stages of a method of manufacturing a semiconductor device according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. In the following embodiments, materials, configurations, dimensions, processes and/or operations as described with respect to one embodiment (e.g., one or more figures) may be employed in the other embodiments, and detailed description thereof may be omitted. Source/drain structure(s) may refer to a source or a drain, individually or collectively dependent upon the context.

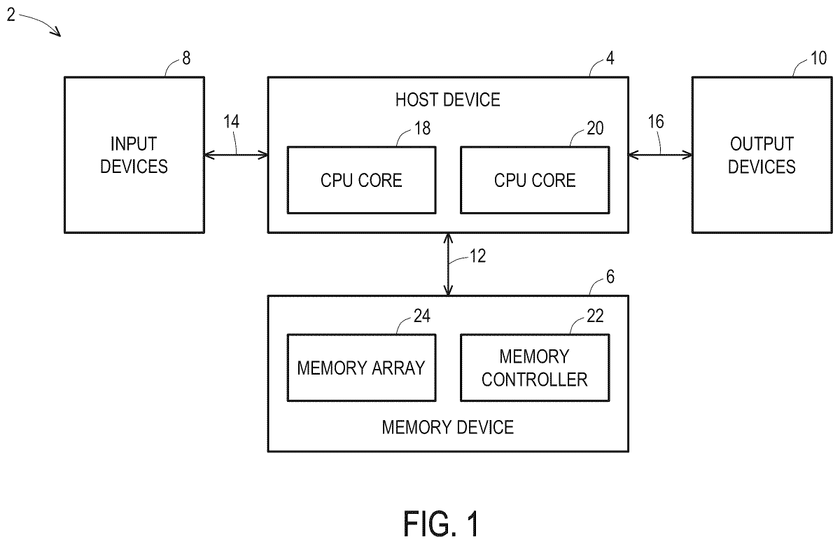

Referring now to FIG. 1, an example block diagram of a computing system 2 is shown, in accordance with some embodiments of the disclosure. The computing system 2 includes a host device 4 associated with a memory device 6. The host device 4 may be configured to receive input from one or more input devices 8 and provide output to one or more output devices 10. The host device 4 may be configured to communicate with the memory device 6, the input devices 8, and the output devices 10 via appropriate interfaces 12, 14, and 16, respectively. The computing system 2 may be implemented in a variety of computing devices such as computers (e.g., desktop, laptop, servers, data centers, etc.), tablets, personal digital assistants, mobile devices, other handheld or portable devices, or any other computing unit suitable for performing any suitable operation using the host device 4.

The input devices 8 may include any of a variety of input technologies such as a keyboard, stylus, touch screen, mouse, track ball, keypad, microphone, voice recognition, motion recognition, remote controllers, input ports, one or more buttons, dials, joysticks, and any other input peripheral that is associated with the host device 4 and that allows an external source, such as a user, to enter information (e.g., data) into the host device and send instructions to the host device. Similarly, the output devices 10 may include a variety of output technologies such as external memories, printers, speakers, displays, microphones, light emitting diodes, headphones, video devices, and any other output peripherals that are configured to receive information (e.g., data) from the host device 4. The “data” that is either input into the host device 4 and/or output from the host device may include any type of data suitable for performing an operation or task such as any one or more of textual data, signal data, graphical data, combinations thereof, or other types of analog and/or digital data that is suitable for processing using the computing system 2.

The host device 4 includes or is associated with one or more processing units/processors, such as a central processing unit (“CPU”) cores 18 and 20. The CPU cores 18 and 20 may be implemented as an application specific integrated circuit (“ASIC”), field programmable gate array (“FPGA”), or any other type of processing unit. Each of the CPU cores 18 and 20 may be configured to execute instructions for running one or more applications of the host device 4. In some embodiments, the instructions and data needed to run the one or more applications may be stored within the memory device 6. The host device 4 may also be configured to store the results of running the one or more applications within the memory device 6. Thus, the host device 4 may be configured to request the memory device 6 to perform a variety of operations. For example, the host device 4 may request the memory device 6 to read data, write data, update or delete data, and/or perform management or other operations.

The memory device 6 includes a memory controller 22 that is configured to read data from or write data to a memory array 24. In some embodiments, the memory array 24 may be a one-time programmable (“OTP”) memory array. The OTP memory array is a type of non-volatile memory that retains the data stored therein after the memory device 6 is powered off. In some embodiments, the OTP memory array may include a plurality of anti-fuse cells, which may be configured to store at least one bit of data.

The memories within the memory array 24 may be individually and independently controlled by the memory controller 22. In other words, the memory controller 22 may be configured to communicate with each memory within the memory array 24 individually and independently. By communicating with the memory array 24, the memory controller 22 may be configured to read data from or write data to the memory array in response to instructions received from the host device 4. Although shown as being part of the memory device 6, in some embodiments, the memory controller 22 may be part of the host device 4 or part of another component of the computing system 2 and associated with the memory device. The memory controller 22 may be implemented as a logic circuit in either software, hardware, firmware, or combination thereof to perform the functions described herein. For example, in some embodiments, the memory controller 22 is configured to retrieve the instructions associated with a desired operation stored in the memory array 24 of the memory device 6 upon receiving a request from the host device 4.

It is to be understood that only some components of the computing system 2 are shown and described in FIG. 1. However, the computing system 2 may include other components such as various batteries and power sources, networking interfaces, routers, switches, external memory systems, controllers, etc. The computing system 2 may include any of a variety of hardware, software, and/or firmware components that are needed or considered desirable in performing any desired functions. Similarly, the host device 4, the input devices 8, the output devices 10, and the memory device 6 including the memory controller 22 and the memory array 24 may include other hardware, software, and/or firmware components that are considered necessary or desirable in performing any desired functions.

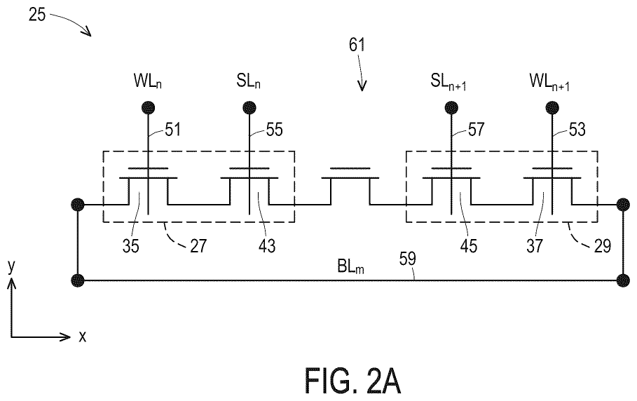

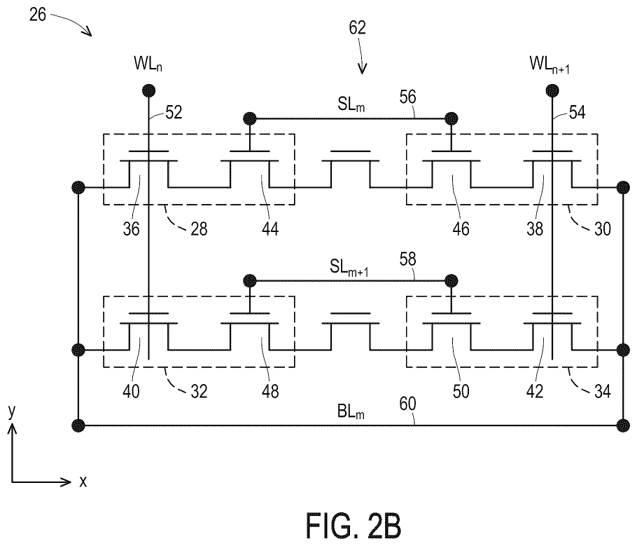

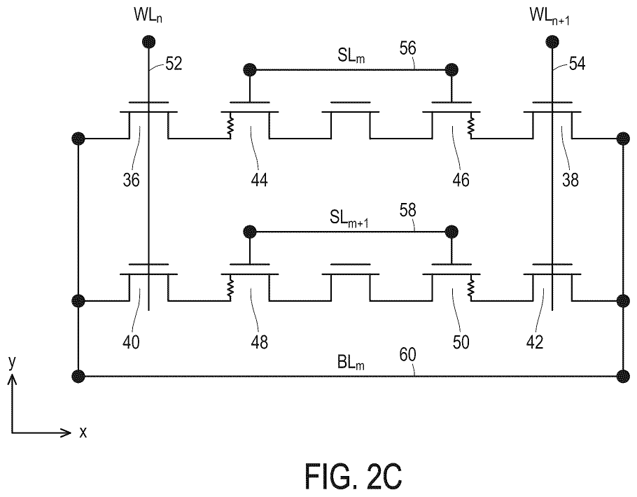

FIG. 2A illustrates an anti-fuse cell array 25 in accordance with some embodiments of the present disclosure. The anti-fuse cell array 25 includes a first anti-fuse cell 27 and a second anti-fuse cell 29 (both shown within dashed boxes in FIG. 2A). In some embodiments, and as shown, each of the first anti-fuse cell 27 and the second anti-fuse cell 29 include two transistors. Thus, the first anti-fuse cell 27 and the second anti-fuse cell 29 are in a 2T cell configuration. Further, the first anti-fuse cell 27 and the second anti-fuse cell 29 may be configured to store one bit of data in some embodiments. Although the anti-fuse cell array 26 has a row including the first anti-fuse cell 27 and the second anti-fuse cell 29, greater or fewer anti-fuse cells may be included in additional cell rows and/or along the same row in the X-direction. Moreover, the first anti-fuse cell 27 and the second anti-fuse cell 29 can be in the form of n-type or p-type transistors. The first and second anti-fuse cells each respectively include a word line transistor 35, 37 and a select line transistor 43 and 45. A first word line 51 (WLₙ) is connected to a gate terminal of word line transistor 35 of the first anti-fuse cell 27 and a second word line 53 (WLₙ₊₁) is connected to a gate terminal of the word line transistor 37 of the second anti-fuse cell 29. A first select line 55 (SLₙ) is connected to gate terminals of select line transistor 43 of the first anti-fuse cell 27, and a second select line 57 (SLₙ₊₁) is connected to gate terminal of select line transistor 45 of the second anti-fuse cell 29. An isolation region 61 resides between the first anti-fuse cell 27 and the second anti-fuse cell 29. A source or drain terminal of the word line transistors 35 and 37 of the first and second anti-fuse cells are connected to a bit line 59 (BLₘ). Thus, the first and second anti-fuse cells include a select line transistor and a word line transistor sharing the bit line 59.

FIG. 2B illustrates an anti-fuse cell array 26 in accordance with some embodiments of the present disclosure. The anti-fuse cell array 26 includes a first anti-fuse cell 28, a second anti-fuse cell 30, a third anti-fuse cell 32, and a fourth anti-fuse cell 34 (each shown within dashed boxes in FIG. 2B). In some embodiments, and as shown, each of the first anti-fuse cell 28, the second anti-fuse cell 30, the third anti-fuse cell 32, and the fourth anti-fuse cell 32 includes two transistors. Thus, each of the first anti-fuse cell 28, the second anti-fuse cell 30, the third anti-fuse cell 32, and the fourth anti-fuse cell 34 is a 2T cell configuration. Further, each of the first anti-fuse cell 28, the second anti-fuse cell 30, the third anti-fuse cell 32, and the fourth anti-fuse cell 34 may be configured to store one bit of data in some embodiments.

Although the anti-fuse cell array 26 has a first row including the first anti-fuse cell 28 and the second anti-fuse cell 30, and a second row arranged along the Y-direction relative to the first row and including the third anti-fuse cell 32 and the fourth anti-fuse cell 34, greater or fewer anti-fuse cells may be included in two or more cell rows, or in a single row along the X-direction. Moreover, the first anti-fuse cell 28, the second anti-fuse cell 30, the third anti-fuse cell 32, and the fourth anti-fuse cell 34 can be in the form of n-type or p-type transistors.

The first, second, third, and fourth anti-fuse cells each respectively include a word line transistor 36, 38, 40, and 42 and a select line transistor 44, 46, 48, and 50. A first word line 52 (WLₙ) is connected to gate terminals of word line transistors 36, 40 of the first and third anti-fuse cells 28, 32, and a second word line 54 (WLₙ₊₁) is connected to gate terminals of word line transistors 38, 42 of the second and fourth anti-fuse cells 30, 34. A first select line 56 (SLₘ) is connected to gate terminals of select line transistors 44, 46 of the first and second anti-fuse cells 28, 30, and a second select line 58 (SLₘ₊₁) is connected to gate terminals of select line transistors 48, 50 of the third and fourth anti-fuse cells 32, 34. The select lines 56, 58 bridge an isolation region 62 respectively between the first anti-fuse cell 28 and the second anti-fuse cell 30 and between the third anti-fuse cell 32 and the fourth anti-fuse cell 34. A source or drain terminal of the word line transistors 36, 38, 40, 42 of each of the first, second, third, and fourth anti-fuse cells are connected to a bit line 60 (BLₘ). Thus, each of the first, second, third and fourth anti-fuse cells includes a select line transistor and a word line transistor sharing the bit line 60.

FIG. 2C illustrates the anti-fuse 26 of FIG. 2A with portions of the select line transistors 44, 46, 48, and 50 exhibiting a state of resistance.

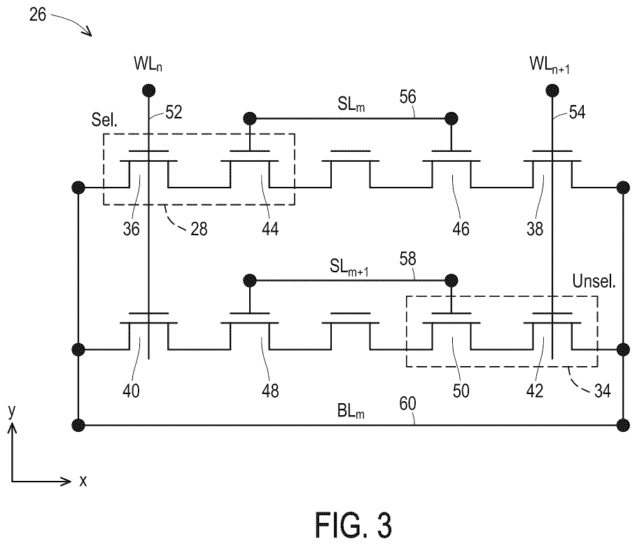

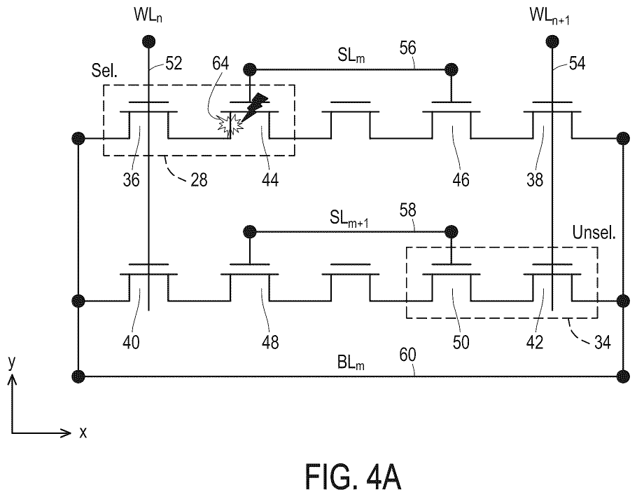

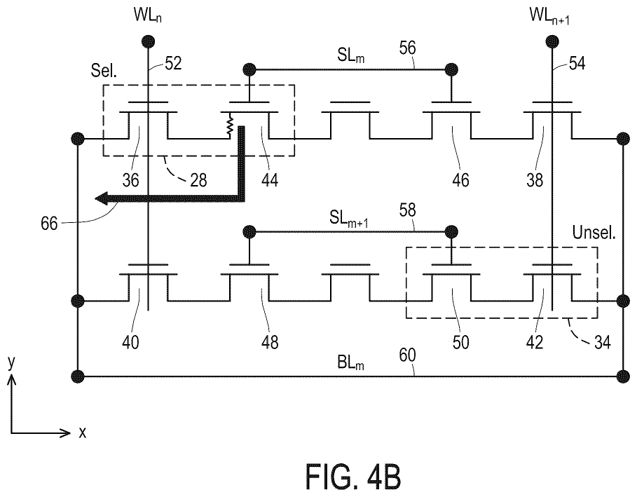

FIG. 3 illustrates the array 26 of FIG. 2B with the first anti-fuse cell 28 designated as selected and the fourth anti-fuse cell 34 designated as unselected, according to an embodiment. FIG. 4A illustrates an embodiment of a process of programming a bit in the first anti-fuse cell 28, with the first anti-fuse cell 28 for programming. In an embodiment, a programming voltage (e.g., 2.5 V) is applied at the first select line 56 to the first select line transistor 44, a lower voltage (e.g., 0.75) is applied to the first word line 52, and a reference voltage (e.g., 0 V) is applied at the bit line 60. The fourth anti-fuse cell 34 is unselected through a floating voltage at the second select line 58 and no voltage to the second word line 54. In some forms, a floating voltage represents a circuit node or pin not being connected to a definite voltage point such as a ground, power supply, or other fixed voltage. A difference between the voltage applied at the first select line 56 and the reference voltage produces an electric field across a gate dielectric layer of the first select line transistor 44. The electric field is sufficiently large to sustainably alter (e.g., break down or fuse 64) the gate dielectric layer of the first select line transistor 44, thereby decreasing the resistance of the gate dielectric layer and programming the data bit(s) in the first select line transistor.

FIG. 4B illustrates an embodiment of a process of reading a bit from the first anti-fuse cell 28 by selecting the first anti-fuse cell 28 for reading. A read voltage (e.g., 0.75 V) is applied at the first select line 56 to the first select line transistor 44, a voltage (e.g., 0.75 V) is applied to the first word line 52, and a reference voltage (e.g., 0 V) is applied at the bit line 60. The fourth anti-fuse cell 34 is unselected through a floating voltage at the second select line 58 and applying no voltage to the second word line 54. The difference between the read voltage and the reference voltage creates an electric field 66 across the dielectric semiconductor layer of the first select line transistor 44. The electric field is sufficiently small to avoid sustainably altering the gate dielectric layer of the first word line transistor 36 but large enough to generate a read current that flows therethrough. The read current flows through the bit line 60 and is sensed by a sense amplifier (not shown) connected to the bit line to read the bit(s) stored within the first select line transistor 44. Bits can be similarly read from second, third, and fourth select line transistors 46, 48, 58.

In another embodiment, a bit is programmed into the first anti-fuse cell 28 by applying a programming voltage (e.g., 3 V) at the first select line 56 to the first select line transistor 44, applying a lower voltage (e.g., 1.2) to the first word line 52, and applying a reference voltage (e.g., 0 V) at the bit line 60. The fourth anti-fuse cell 34 is unselected by a floating voltage at the second select line 58 and applying no voltage to the second word line 54. In a process of reading a bit from the first anti-fuse cell 28 includes applying a read voltage (e.g., 0.8 V) at the first select line 56 to the first select line transistor 44, applying a voltage (e.g., 0.8 V) to the first word line 52, and applying a reference voltage (e.g., 0 V) at the bit line 60. The fourth anti-fuse cell 34 is unselected by a floating voltage at the second select line 58 and applying no voltage at the second word line 54.

To reduce the overall cell area of the anti-fuse cell array 26, the present disclosure, in various embodiments, provides a mechanism of enabling the first and second anti-fuse cells 28,30, and the third and fourth anti-fuse cells 32,34, to be formed on common active regions. In various forms, a common active region can of one or more three-dimensional field-effect-transistors (e.g., FinFETs, nanosheet, gate-all-around (GAA) transistors), or an oxide-definition (OD) region of one or more planar metal-oxide-semiconductor field-effect-transistors (MOSFETs), such that the active region may serve as a source feature or drain feature of the respective transistor(s). In various forms, a common active region can extend along the cell row direction. A common active region can include source/drain structures formed by growing a strained source/drain material between channel regions or sacrificial gates via an epitaxial (epi) process. A lattice constant of the strained material may be different from the lattice constant of the substrate on which the epitaxially-formed common active region is formed. Accordingly, epitaxially-formed source/drain material can serve as stressors to improve carrier mobility. According to some embodiments, epitaxially-formed source/drain material includes silicon germanium, carbon-doped silicon, or silicon. Depending on the type of transistor formed, e.g., a p-type or an n-type transistor, a p-type or an n-type impurity may be in-situ doped during the process of forming an epitaxially-formed source/drain material. For example, when a resulting transistor is a p-type, silicon germanium boron (SiGeB) may be grown. Conversely, when a resulting transistor is an n-type, silicon phosphorous (SiP) or silicon carbon phosphorous (SiCP) may be grown. In some embodiments, a source/drain material may be implanted with a p-type or an n-type impurity as needed. Implantation can be skipped when a source/drain material is in-situ doped with the p-type or n-type impurity during an epitaxy process. In some forms, common active regions include lower portions that are formed in shallow trench isolation (“STI”) regions, and upper portions that are formed over the top surfaces of STI regions.

Any embodiment of a semiconductor device in the present disclosure can include one or more common active regions including one of an n-type material or a p-type material formed over a substrate that includes the other of the n-type or the p-type material.

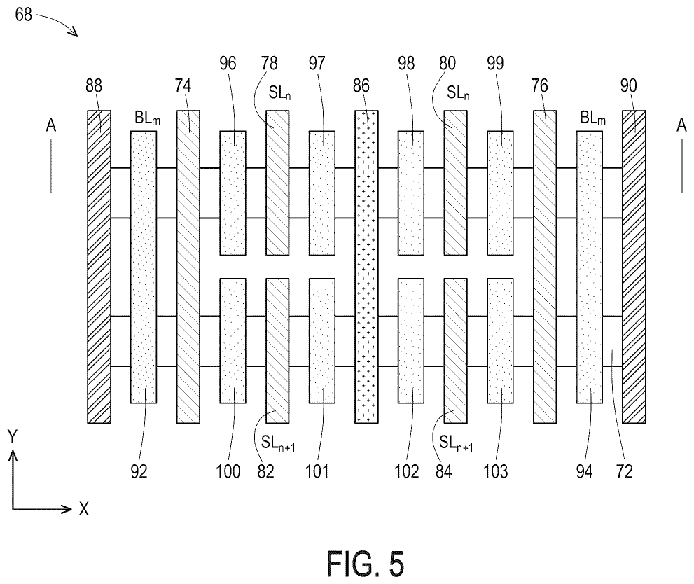

FIGS. 5-7B illustrate various views of a semiconductor device 68 including a circuit shown in FIG. 2B, according to embodiments. FIG. 5 illustrates a plan view of the device 68 including a first common active region 70 and a second common active region 72 each extending in the X-direction. A first gate line 74 extends in the Y-direction and intersects both the first and second common active regions 70, 72. The first gate line 74 corresponds to the first word line 52 (WLₙ) shown in FIG. 2B. A second gate line 76 extends in the Y-direction and also intersects both the first and second common active regions 70, 72. The second gate line 76 corresponds to the second word line 54 (WLₙ₊₁) shown in FIG. 2B.

A third gate 78 line extends in the Y-direction and intersects the first common active region 70 between the first and second gate lines 74, 76. A fourth gate line 80 extends in the Y-direction and intersects the first common active region 70 between the second and third gate lines 76, 78. The third and fourth gate lines 78, 80 do not intersect the second common active region 72. The third and fourth gate lines 78, 80 together correspond to the first select line 52 (SLₘ) shown in FIG. 2B through an electrical connection between third and fourth gate lines 78, 80, which is not shown in FIG. 5 to simplify the illustration.

A fifth gate line 82 extends in the Y-direction in alignment with the third gate line 78 and intersects the second common active region 72 between the first and second gate lines 74, 76. A sixth gate line 84 extends in the Y-direction in alignment with the fourth gate line 80 and intersects the second common active region 72 between the second and fifth gate lines 76, 82. The fifth and sixth gate lines do not intersect the first common active region 70. The fifth and sixth gate lines 82, 84 together correspond to the second select line 58 (SLₘ₊₁) shown in FIG. 2B through an electrical connection between fifth and sixth gate lines 82, 84, which is not shown in FIG. 5 to simplify the illustration.

In some embodiments, dummy polycrystalline silicon (poly) segments formed on edges of a silicon oxide definition (OD) region such as an active region of a standard cell, i.e., poly-on-OD-edge (PODE). To minimize the current leakage from active regions, in some embodiments a PODE can be provided. In some embodiments, a PODE can be provided at ends of one or more active regions to protect the active regions. In some embodiments, a PODE is provided through an active region shared by anti-fuse cells and can be considered a common PODE or continuous PODE (also referred to herein as CPODE). A CPODE can be provided in a region where a gap would have been provided in a conventional standard cell. In some embodiments, a PODE or CPODE may be formed using a STI technique. During fabrication of an anti-fuse cell array, a PODE or CPODE may be created by forming a trench in the semiconductor wafer on which the anti-fuse cell array is being fabricated, and the trench may be deposited with a dielectric material. By virtue of using a dielectric material, a PODE or CPODE does not provide an electrical or conductive path, and may prevent or at least reduce/minimize current leakage across components between which the PODE or CPODE is located.

In FIG. 5, the first common active region 70 is shared by the first and second anti-fuse cells 28, 30 shown in FIG. 2B, and the second common active region 72 is shared by the third and fourth anti-fuse cells 28, 30 shown in FIG. 2B. The device 68 includes a CPODE 86 as a first isolating structure. The CPODE 86 is provided in a region corresponding to the isolation 62 in FIG. 2B. The CPODE 86 extends in the Y-direction and through the first common active region 70 between the third and fourth gate lines 78, 80, and through the second common active region 72 between the fifth and sixth gate lines 82,84. The CPODE 86 includes a trench filled with a dielectric material that extends into a substrate to a depth below the first and second common active regions 70, 72. Opposite sides of the CPODE along the X-direction contact the first and second common active regions 70, 72. The CPODE divides the first common active region between the first and second anti-fuse cells and divides the second common active region 72 between the third and fourth anti-fuse cells 28, 30. Electrical connections between the third and fourth gate lines 78, 80 and between the fifth and sixth gate lines 82, 84 (not shown in FIG. 5 to simplify the illustration) exist and bridge across the CPODE. By implementing CPODE in the isolation region of the anti-fuse array, and by bridging select lines over an isolation region, the overall cell area of a semiconductor device can be reduced, and the total number of pins, e.g., accounting for word lines, select lines, and bit lines, can be reduced.

The device 68 includes a PODE 88 and PODE 90 as isolating structures. PODE 88 extends in the Y-direction and intersects the first and second common active regions 70,72 proximal to the first gate line 74. PODE 90 extends in the Y-direction and intersects the first and second common active regions 70, 72 proximal to the second gate line 78.

The device further includes a first metal over diffusion line 92 that extends in the Y-direction and contacts the first and second common active regions 70, 72, and a second metal over diffusion 94 line that extends in the Y-direction and contacts the first and second common active regions 70, 72. The first and second gate lines 74, 76 are between the first and second metal over the diffusion lines 92, 94. An electrical connection exists between the first and second metal over the diffusion lines 92,94 but is not shown in FIG. 5 to simplify the illustration. The first and second metal over diffusion lines 92, 94 are connected to the bit line 60 (BLₘ) shown in FIG. 2. The device also includes a third metal over the diffusion line 96, a fourth metal over the diffusion line 97, a fifth metal over the diffusion line 98, and a sixth metal over the diffusion line 99 each extending in the Y-direction and contacting the first common active region 70. The third, fourth, fifth and sixth metal over the diffusion lines 96, 97, 98, 99 do not contact the second common active region 72. The device further includes a seventh metal over the diffusion line 100, an eighth metal over the diffusion line 101, a ninth metal over the diffusion line 102, and a tenth metal over the diffusion line 103, each extending in the Y-direction and contacting the second common active region 72. The seventh, eighth, nineth and tenth metal over the diffusion lines 100, 101, 102, 103 do not contact the first common active region 70.

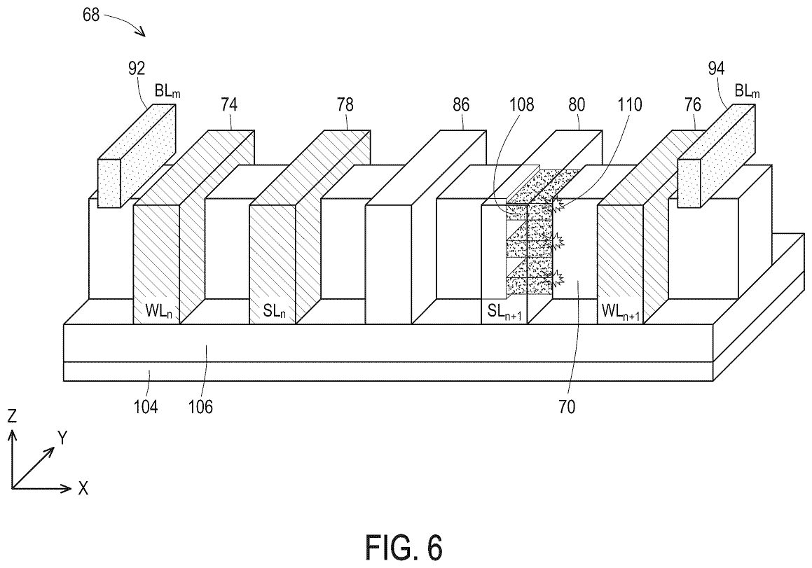

FIG. 6 illustrates a partial perspective view of the device 68 shown in FIG. 5. An isolation 106 region is disposed over a substrate 104. The first and second common active regions 70, 72 are disposed over the substrate 104 and protrude above the isolation region 106 in the Z-direction. Only the first common active region 70 is shown in FIG. 6. The first, second, third, and fourth gate lines 74, 76, 78, 80 are shown intersecting the first common active region 70, and the first isolating structure 86 intersects the first common active region between the third and fourth gate lines 78, 80. Gate line 80 is illustrated transparently to show area 110 and semiconductor layers 108. In area 110, a gate dielectric material of the gate line can transform from an anti-fuse to a fuse structure upon application of a sufficient voltage. The first common active region 70 includes the source and drain terminals of the word line transistors 36, 38 and the select line transistors 44, 46 of the first anti-fuse cell 28 and the second anti-fuse cell 30 shown in FIG. 2B. The first gate line 74 corresponds to the first word line (WLₙ) of the first word line transistor 36 shown in FIG. 2B. The second gate line 76 corresponds to the second word line (WLₙ₊₁) of the second word line transistor 38 shown in FIG. 2B. The third and fourth gate lines 78, 80 correspond to the first select line (SL connected between the first and second select line transistors 44, 46 shown in FIG. 2B. The first common active region 70 is connected to the bit line 60 (BLₘ) of FIG. 2B via the first and second metal over diffusion lines 92, 94. To simplify the illustration, the third, fourth, fifth, sixth, seventh, eighth, nineth, and tenth metal over diffusion lines 96, 87, 98, 99, 100, 101, 102, 103 shown in FIG. 5 are omitted from FIG. 6.

Area 110 illustrates a location where a gate dielectric material of a gate line can transform from an anti-fuse to fuse structure upon application of a sufficient voltage. A stack of semiconductor layers 108 is schematically illustrated. In the illustrated embodiment, the semiconductor layers 108 are aligned with and extend the length of the first common active region through channel regions of the first, second, third, and fourth gate lines 74, 76, 78, 80 and through sections of the first common active region between the gate lines. In alternate embodiments, semiconductor layers reside in channel regions of the gate lines, but no semiconductor layers reside in sections of a common active region between the channel regions, and the common active region includes epitaxially formed source/drain structures between channel regions of gate lines without the semiconductor layers.

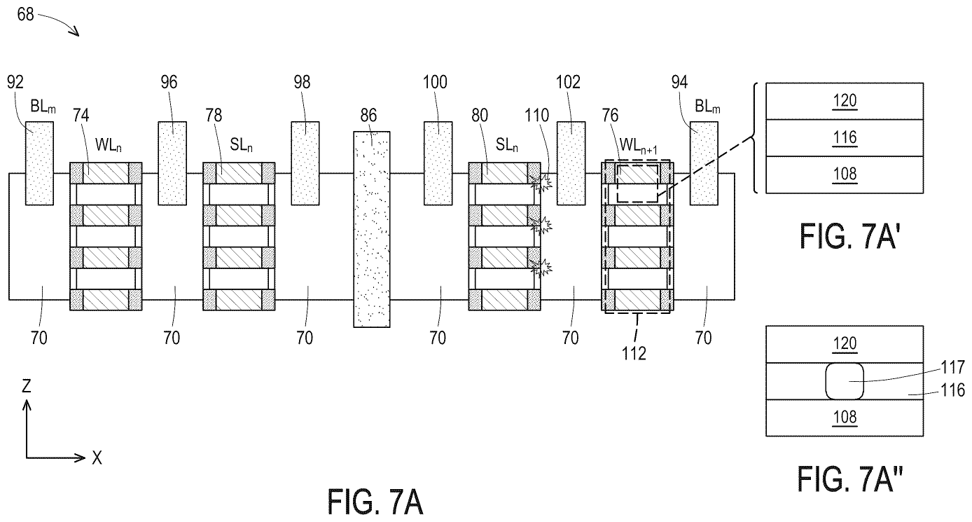

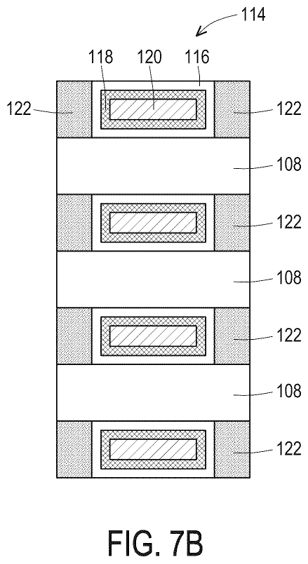

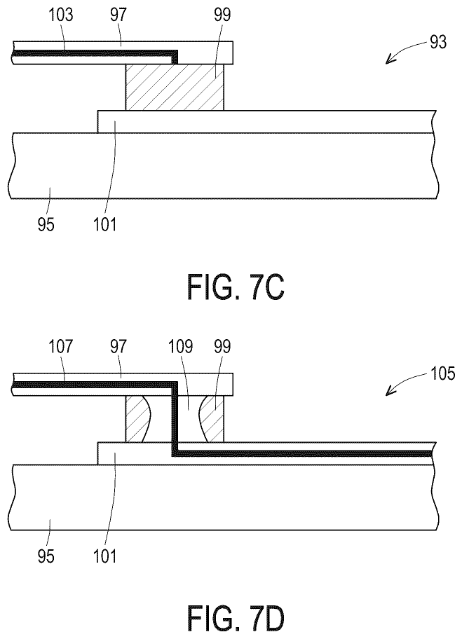

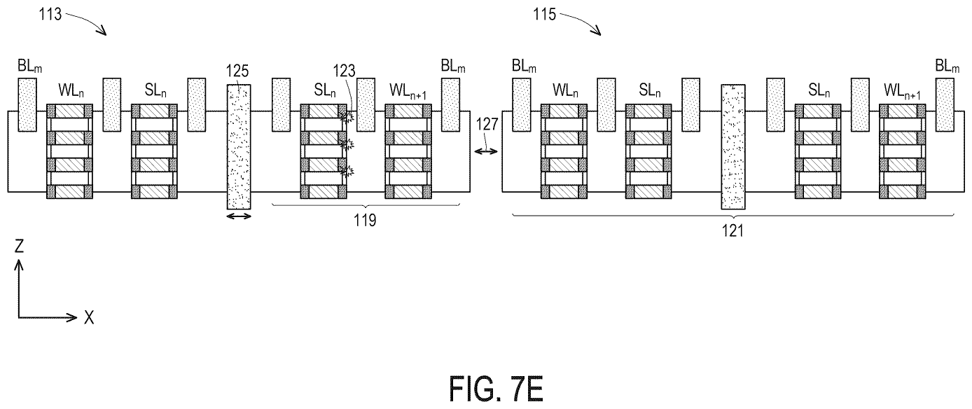

FIG. 7A illustrates a partial cross-section of the device 68 taken along the X-direction at A-A in FIG. 5. The substrate and isolation region of FIG. 6 are omitted to simplify the illustration of FIG. 7A. FIG. 7A′ schematically illustrates an enlarged portion area 110 where a gate dielectric material 116 between a gate material 120 and a semiconductor layer 108 can transform from an anti-fuse to fuse structure upon application of a sufficient voltage, according to some embodiments. FIG. 7A″ schematically illustrates the area shown in FIG. 7A′ upon application of sufficient voltage across gate dielectric material 116 to form a conductive fuse structure 117 therein, according to some embodiments.

FIG. 7B illustrates the channel region within box 112 over the second gate line 76 in FIG. 7A, according to some embodiments. The channel region 112 includes the stack of semiconductor layers 108 and gate structures 114 surrounding the semiconductor layers. The semiconductor layers function as channel structures and penetrate through the gate line in the X-direction toward the source/drain structures of the first common active region 70. The gate structures 114 respectively include a gate dielectric layer 116, a work function layer 118, and a gate material 120. Inner spacers 122 are formed on opposite sides of the gate material 120. The gate material 120 is surrounded by the work function material 118, and the work function material 118 is surrounded by the gate dielectric layer 116. The gate dielectric layer 116 is between the gate material 120 and the semiconductor layers 108 and between the gate material 120 and the source/drain structures of the first common active region 70. The gate dielectric layer 116 is configured to function as an anti-fuse structure that is convertible to a fuse structure through application of a sufficient voltage to the gate line. Each of the first, second, third, fourth, fifth and sixth gate lines 74, 76, 78, 80, 82, 84 include a channel region as illustrated in FIG. 7B, in some embodiments.

FIG. 7C schematically illustrates an anti-fuse structure 93 formed over a substrate 95, according to embodiments. The substrate is a silicon substrate in some embodiments. The anti-fuse structure 93 includes an upper metal layer (or upper metal oxide layer) 97 disposed in contact with an insulating layer 99 (e.g., gate dielectric layer), and the insulating layer 99 is disposed over a lower metal layer (or lower metal oxide layer) 101. In some embodiments, the insulating layer is made of amorphous silicon. In FIG. 7C, a current 103 is applied through the upper metal layer 97 at a voltage insufficient to cause substantial degradation or breakdown of the insulating layer 99. Thus, the insulating layer 99 exhibits higher resistance than the upper metal layer 97. Thus, the current 103 does not pass through the insulating layer 99. FIG. 7D schematically illustrates a fuse structure 105 formed by applying current 107 through the upper metal layer 97 at a sufficient voltage to cause a breakdown of a portion of the insulating layer 99 into a conductive material 109. Thus, the conductive material has a resistance equal to or less than the upper metal layer 97. In some embodiments, the conductive material is polysilicon.

FIG. 7E illustrates a partial cross-section of an array including two devices 113 and 115 each having the structure of the device 68 shown in FIG. 7A. Device 113 includes a selected region 119 and device 115 includes an unselected region 121. The selected region has an area 123 where a gate dielectric material of a gate line can transform from an anti-fuse to fuse structure upon application of a sufficient voltage. The isolation region 125 of device 113 enables a much narrower spacing than the spacing 127 provided between the two devices 113, 115.

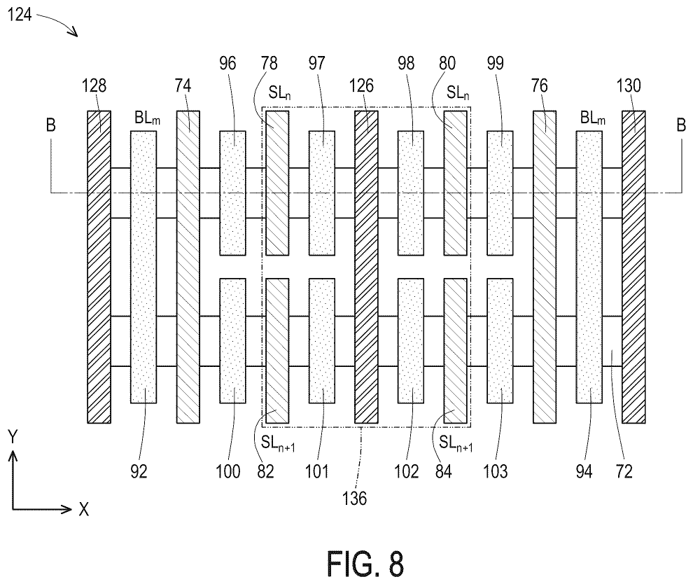

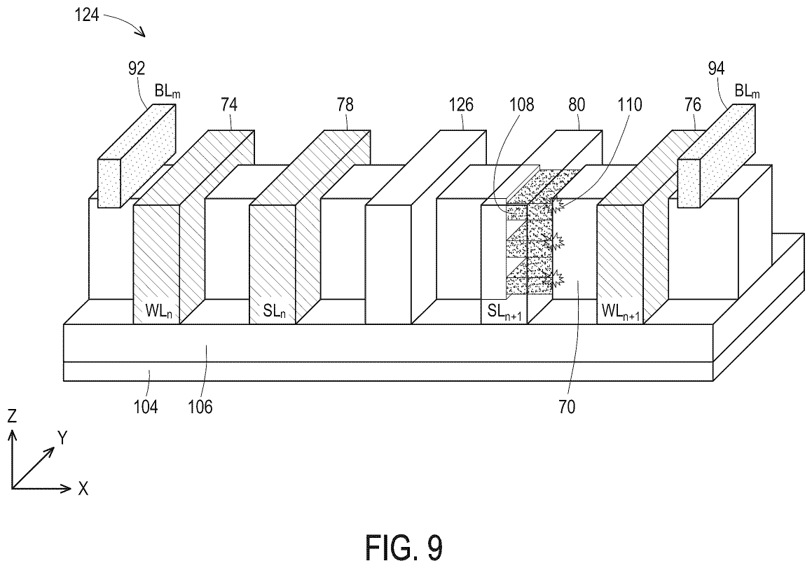

FIGS. 8, 9, 10A, and 10B illustrate various views of a semiconductor device 124 including a circuit shown in FIG. 2B, according some embodiments. FIG. 8 is a plan view, and FIG. 9 is a perspective view of the semiconductor device 124. Elements of the device 124 shown in FIGS. 8-10B having the same structure as provided in the device 68 shown in FIGS. 5-7B are numbered identically in FIGS. 8-10B. The device 124 includes a first sacrificial gate line 126 in a region corresponding to the isolation 62 in FIG. 2B. The first sacrificial gate line 126 extends in the Y-direction and through the first and second common active regions 70, 72 between the third and fourth gate lines 78, 80 and between the fifth and sixth gate lines 82, 84. The device 124 further includes second and third sacrificial gate lines 128,130 that extend in the Y-direction. The second sacrificial gate line 128 intersects the first and second common active regions 70, 72 proximal to the first gate line 74, and the third sacrificial gate line 130 intersects the first and second common active regions 70, 72 proximal to the second gate line 76.

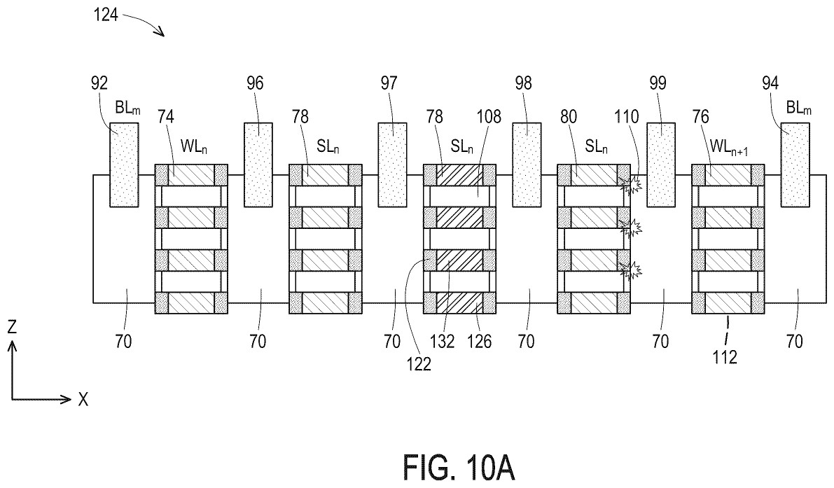

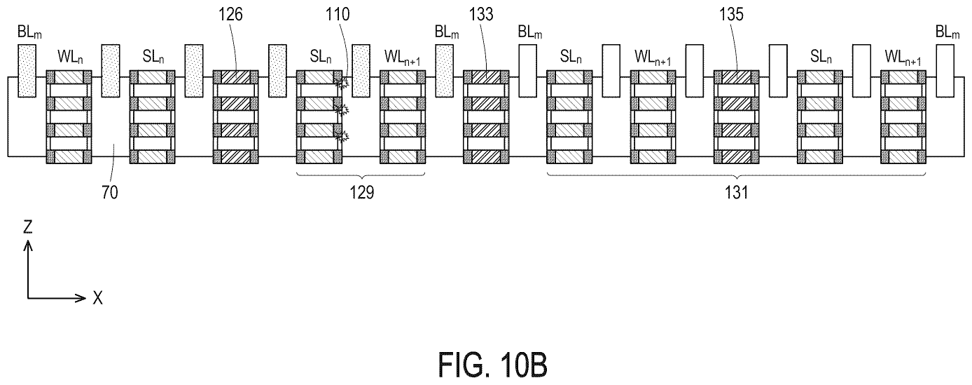

FIG. 10A illustrates a partial cross-section taken along the X-direction at B-B in FIG. 8. The first sacrificial gate line 126 includes a stack of semiconductor layers 108 and a sacrificial dielectric 132 between the semiconductor layers and over an upper semiconductor layer in the stack. Inner spacers 122 are formed on opposite sides of the sacrificial dielectric 132. The second and third sacrificial gates 128, 130 can have the same or different structure as the first sacrificial gate 126, and are omitted from FIG. 10A to simplify illustration. By implementing a sacrificial gate line, overall cell area of a semiconductor device can be even further reduced.

FIG. 10B illustrates a modification of the device shown in FIG. 10A to have a longer common active region 70 and three sacrificial gate lines 126, 133, 135, according to some embodiments. A selected cell 129 has an area 110 where a gate dielectric material of a gate line can transform from an anti-fuse to a fuse structure upon application of a sufficient voltage. Unselected area 131 does not have the transformed area 110. The insulating sacrificial gate 133 can reduce the spacing between the selected and unselected areas 129, 135.

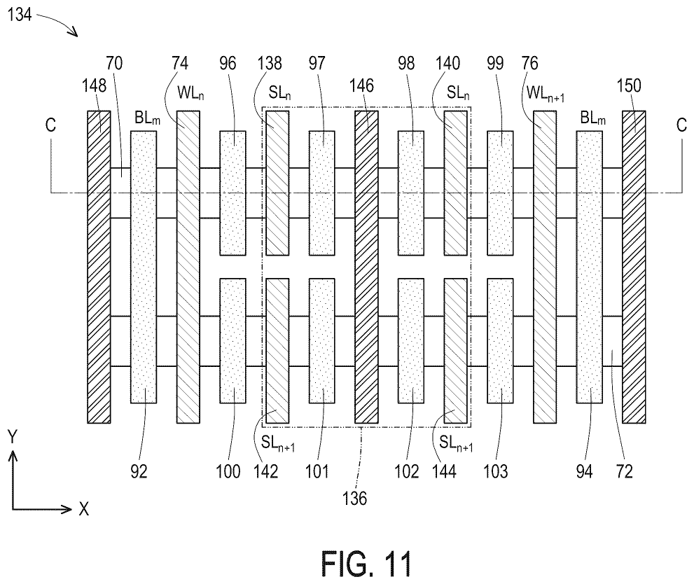

FIGS. 11-13D illustrate various views of a semiconductor device 134 including a circuit shown in FIG. 2B, according to embodiments. Elements of the device 134 shown in FIGS. 11-13D having the same structure as provided in the device 68 shown in FIGS. 5-7B are numbered identically in FIGS. 11-13D. The device 134 includes a region 136 bounded by the dashed box which surrounds a third gate line 138, a fourth gate line 140, a fifth gate line 142, and a sixth gate line 144 each extending in the Y-direction and including focused anti-fuse structures as described below. The third and fourth gate lines 138,140 intersect the first common active region 70 and the fifth and sixth gate lines 142, 144 intersect the second common active of region 72. The third and fourth gate lines 138, 140 do not intersect the second common active region 72 and the fifth and sixth gate lines 142, 144 do not intersect the first common active region 70.

The device 134 includes a plural dielectric sacrificial gate line 146 as a first isolating structure. The plural dielectric sacrificial gate line 146 extends in the Y-direction and intersects the first common active region 70 between the third and fourth gate lines 138, 140 and intersects the second common active region 72 between the fifth and sixth gate lines 142, 144. The third and fourth gate lines 138, 140 together correspond to the first select line 52 (SLₘ) shown in FIG. 2 through an electrical connection that bridges the sacrificial gate 146 between third and fourth gate lines 138, 140, which is not shown in FIG. 11 to simplify the illustration. In the same manner, the fifth and sixth gate lines 142, 144 together correspond to the second select line 58 (SLₘ₊₁) shown in FIG. 2B.

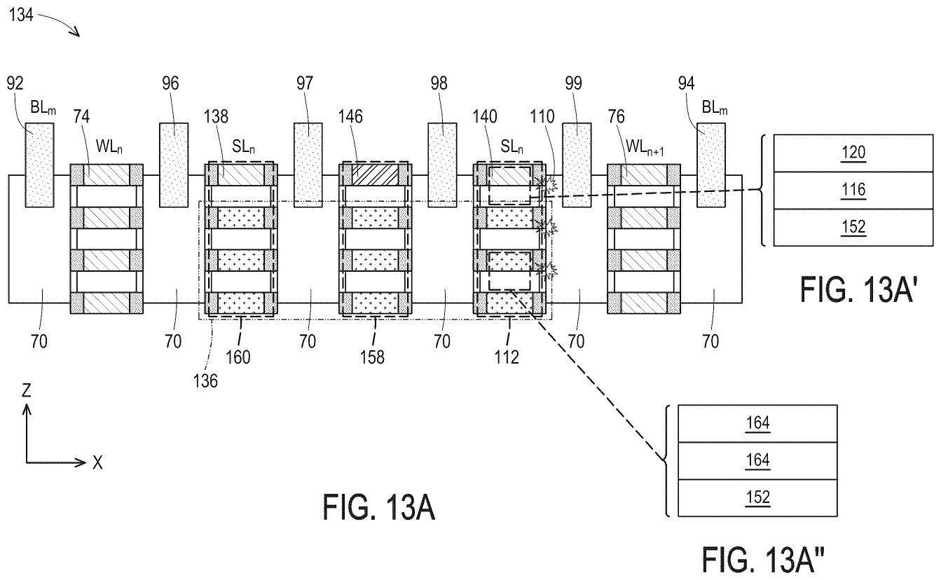

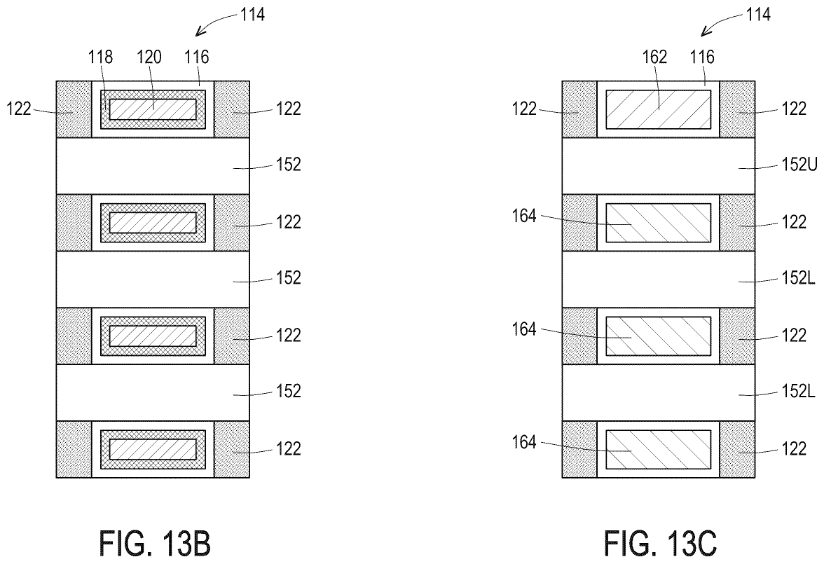

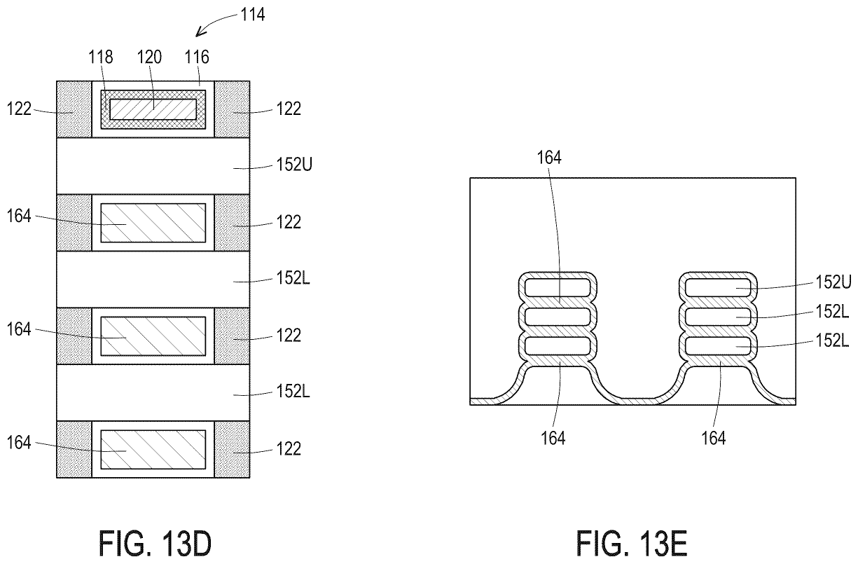

The device 134 further includes isolating structures 148, 150 which extend in the Y-direction and intersect the first and second common active regions 70, 72. The first and second gate lines 74, 76 are between the isolating structures 148, 150. The isolating structures 148, 150 can each independently have the structure of the first sacrificial gate line 126 shown in FIG. 10A, a PODE, the structure of the plural dielectric sacrificial gate line shown in FIG. 13A, or any other useful isolating structure.

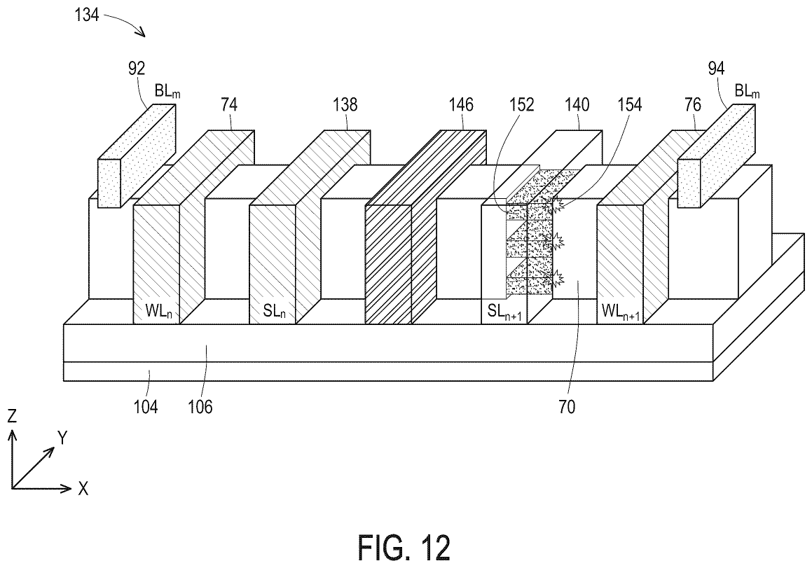

FIG. 12 illustrates a perspective view of a portion of the device 134 shown in FIG. 11 including first common active region 70 and a portion of region 136 including the third and fourth gate lines 138, 140 and the plural dielectric sacrificial gate line 146. The first, second, third, and fourth gate lines 74, 76, 138, 140 and the plural dielectric sacrificial gate line 146 intersect the first common active region 70. Gate line 140 is illustrated transparently to show area 154 and semiconductor layers 152. Area 154 illustrates a location where a gate dielectric material of a gate line can transform from an anti-fuse to fuse structure upon application of a sufficient voltage. Sufficient voltage can be applied when designating cell 30 as a selected cell. In some embodiments, the semiconductor layers 152 in the common active region between the second and fourth gate lines 76, 140 are aligned with and extend the length of the first common active region through channel regions of the first, second, third, and fourth gate lines 74, 76, 138, 140 and through sections of the first common active region between the gate lines. In alternate embodiments, semiconductor layers reside in channel regions of the gate lines, but no semiconductor layers reside in sections of a common active region between the channel regions, and the common active region includes epitaxially formed source/drain structures between channel regions of gate lines without the semiconductor layers.

FIG. 13A illustrates a cross-section of a portion of device 134 taken along the X-direction at C-C in FIG. 11. FIG. 13A′ further illustrates an enlarged portion area 154 where a gate dielectric material 116 formed around gate material 120 can transform from an anti-fuse to a fuse structure upon application of a sufficient voltage, according to some embodiments. The gate dielectric material 116 is disposed between the gate material 120 and a semiconductor layer 152. FIG. 13A″ further illustrates another enlarged region where a second dielectric material 164 is formed instead of a gate dielectric material 116 and gate material 120 shown in FIG. 13A′, according to some embodiments. In FIG. 13A″, the second dielectric material 164 is formed as multilayer. Alternatively, second dielectric material can be formed as a monolayer.

FIG. 13B illustrates the channel region within box 156 over the second gate line 76 in FIG. 13A. The channel region 156 includes a stack of semiconductor layers 152 and a gate structure 114 surrounding semiconductor layers. Semiconductor layers function as channel structures and penetrate through the gate line in the X-direction toward the source/drain structures of the first common active region 70. The gate structure 114 includes a gate dielectric layer 116, a work function layer 118, and a gate material 120. Inner spacers 122 are formed on opposite sides of the gate material 120. The gate material 120 is surrounded by the work function material 118, and the work function material 118 is surrounded by a gate dielectric layer 116. The gate dielectric layer 116 is between the gate material 120 and the semiconductor layers 152 and between the gate material 120 and the source/drain structures of the first common active region 70.

FIG. 13C illustrates the channel region within box 158 over the plural dielectric sacrificial gate line 146 in FIG. 13A. The channel region 158 of the plural dielectric sacrificial gate line 146 includes a first dielectric material 162 and a second dielectric material 164. The first dielectric material 162 is disposed over an upper semiconductor layer 152U of the channel region and is surrounded by a gate dielectric layer 116. The second dielectric material 164 is disposed under the upper semiconductor layer 152U and between the semiconductor layers 152L below the upper semiconductor layer. The second dielectric material 164 is surrounded by a gate dielectric layer 116. In some forms, the first and second dielectric materials are different. In some forms, the first dielectric material can include an insulator such as silicon dioxide or silicon nitride, and the second dielectric material can include an insulator such as aluminum oxide. In other forms, the first and second dielectric materials are the same. Inner spacers 122 are formed on opposite sides of the first and second dielectric materials 162, 164 in the channel region.

FIG. 13D illustrates a focused anti-fuse structure of the third and fourth gate lines 138, 140 within boxes 160, 161 over the channel regions in FIG. 13A. A gate structure 114 is provided over the upper semiconductor layer 152U. The gate structure 114 includes a gate dielectric layer 116, a work function layer 118, and a gate material 120. The gate dielectric layer 116 is between the gate material 120 and the semiconductor layer 152U and between the gate material 120 and the source/drain structures of the first common active region 70. The gate dielectric layer 116 is configured to function as an anti-fuse structure convertible to a fuse structure through application of a sufficient voltage to the third and fourth gate lines 138, 140. The second dielectric material 164 is disposed under the upper semiconductor layer 152U and between the semiconductor layers 152L below the upper semiconductor layer 152U. The second dielectric material is surrounded by a gate dielectric layer 116. Inner spacers 122 are formed on opposite sides of the gate material 120 and the second dielectric material 164 at different levels of the channel region.

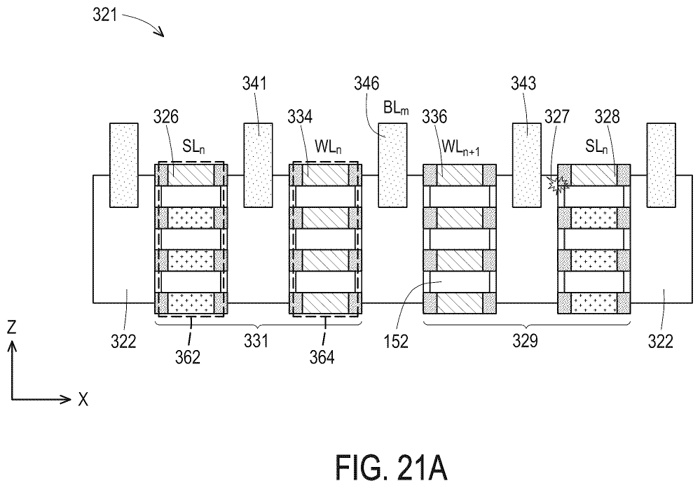

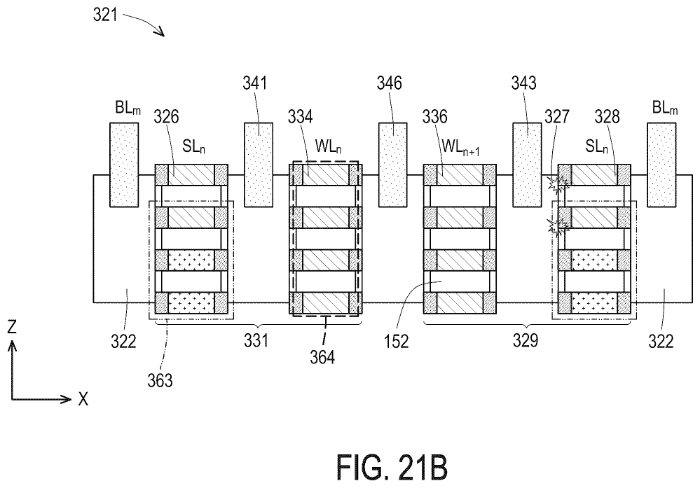

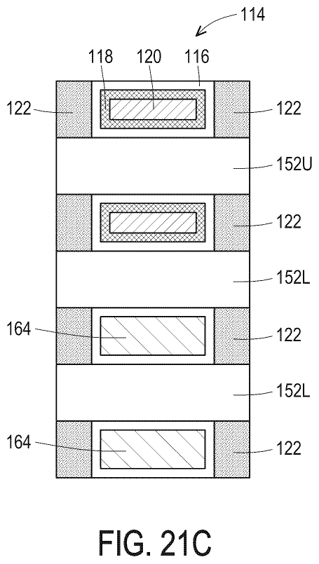

Given that the anti-fuse structure of the third and fourth gate lines 138, 140 is concentrated or focused at a single level, on cell current through the anti-fuse structure can be more easily controlled relative to the gate lines including plural anti-fuse structures. In a channel region having a focused anti-fuse structure, a gate structure 114 can be provided at any level in a channel region, such as at the bottom, the top, or any intermediate level between semiconductor layers, and the remaining layers between the semiconductor layers can include dielectric material. By implementing a sacrificial gate line and gate lines including focused anti-fuse structures, overall cell area of a semiconductor device can be reduced and a breakdown point of an anti-fuse structure can be controlled to improve variation in on-cell current and attenuate channel inversion generation. In some embodiments, the third and fourth gate lines 138, 140 can have the structure shown in FIG. 21C discussed below.

FIG. 13E illustrates an embodiment of a channel region of a device including layers 152U, 152L of semiconductor material. A second dielectric material 164 having a different dielectric constant is formed between the layers 152U, 152L before applying a gate structure above the upper semiconductor layer 152U.

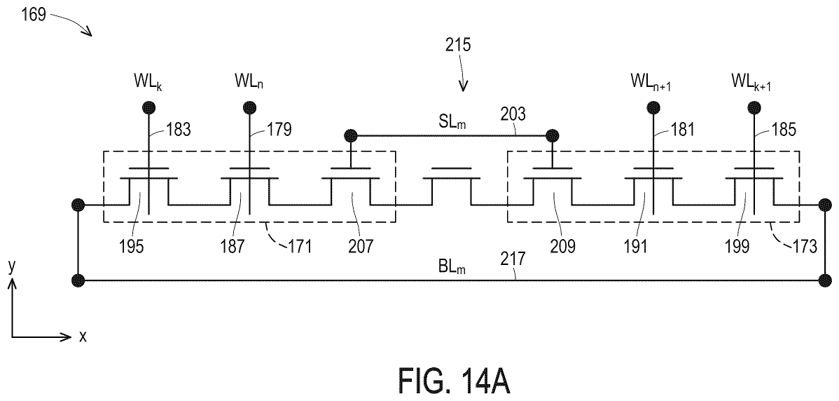

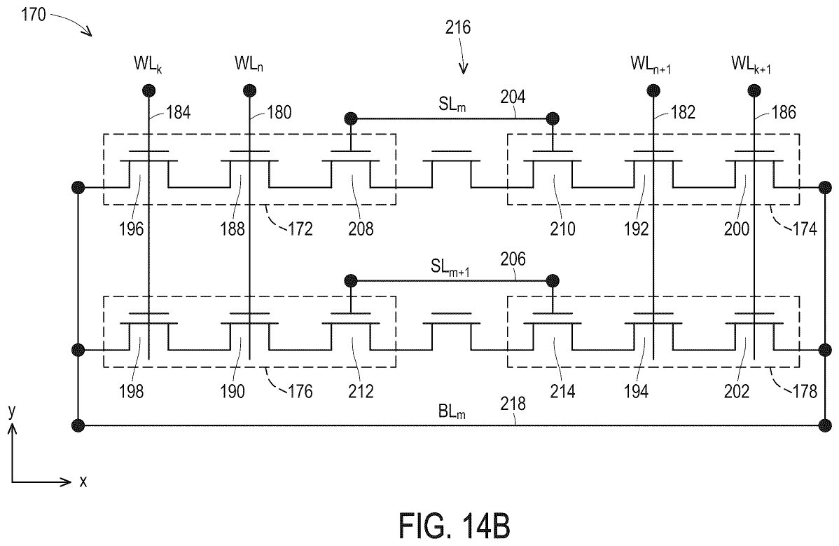

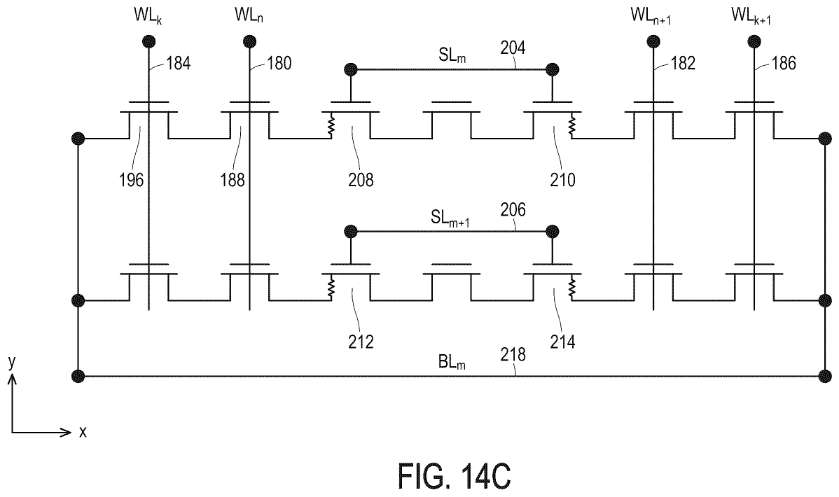

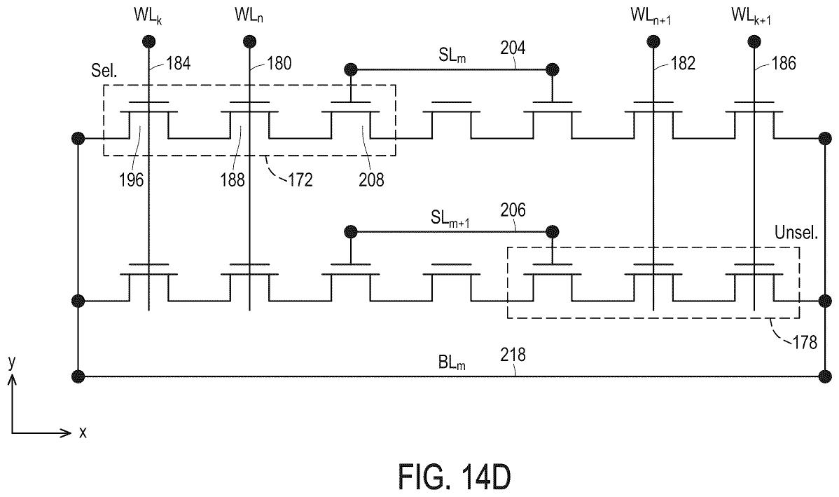

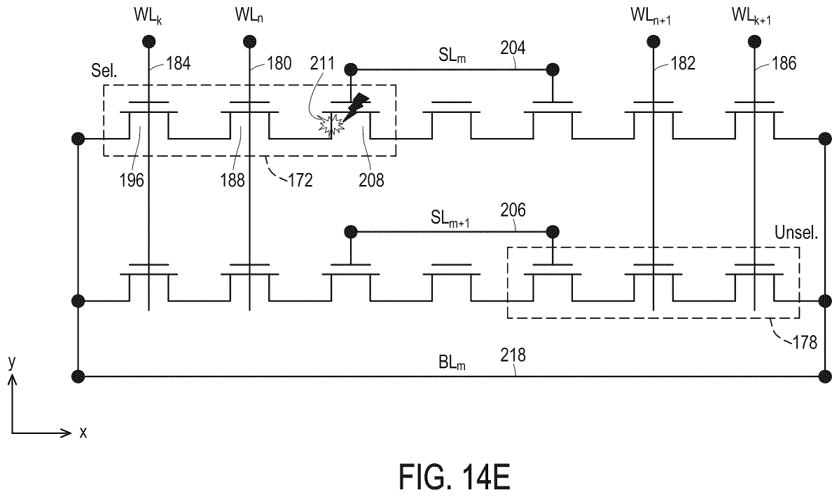

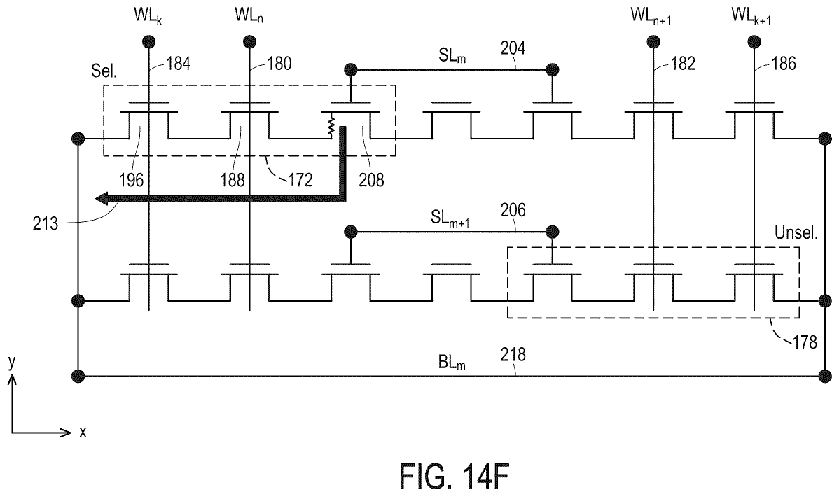

FIG. 14A illustrates an anti-fuse cell array 169 in accordance with embodiments of the present disclosure. The anti-fuse cell array 169 includes a first anti-fuse cell 171 and a second anti-fuse cell 173 (both shown within dashed boxes in FIG. 14A). In some embodiments, and as shown, the first and second anti-fuse cells 171, 173 both include three transistors. Thus, both of the first and second anti-fuse cells 171, 173 are in a 3T cell configuration. Although the anti-fuse cell array 169 has a row including the first anti-fuse cell 171 and the second anti-fuse cell 173, greater or fewer anti-fuse cells may be included in two or more cell rows, and/or in the same row along the X-direction. Moreover, the first anti-fuse cell 171 and the second anti-fuse cell 173 can be in the form of n-type or p-type transistors. The first and second anti-fuse cells 171, 173 each respectively include two word line transistors and a select line transistor. A first word line 179 (WLₙ) is connected to a gate terminal of word line transistor 187 of the first anti-fuse cell 171, and a second word line 181 (WLₙ₊₁) is connected to a gate terminal of word line transistor 191 of the second anti-fuse cell 173. A third word line 183 (WLₖ) is connected to a gate terminal of a word line transistor 195 of the first anti-fuse cell 171, and a fourth word line 185 (WLₖ₊₁) is connected to a gate terminal of word line transistor 199 of the second anti-fuse cell 173. A select line 203 (SLₘ) is connected to gate terminals of the select line transistors 207,209 of the first and second anti-fuse cells 171, 173. The select line 203 bridges an isolation 215 respectively between the first anti-fuse cell 171 and the second anti-fuse cell 173. A source or drain terminal of the word line transistors 195, 199 of the first and second anti-fuse cells are connected to a bit line 217 (BLₘ). Thus, the first and second anti-fuse cells include a select line transistor and two word line transistors sharing the bit line 217.

FIG. 14B illustrates an anti-fuse cell array 170 in accordance with embodiments of the present disclosure. The anti-fuse cell array 170 includes a first anti-fuse cell 172, a second anti-fuse cell 174, a third anti-fuse cell 176, and a fourth anti-fuse cell 178 (each shown within dashed boxes in FIG. 14B). In some embodiments, and as shown, each of the first, second, third, and fourth anti-fuse cells 172, 174, 176, 178 includes three transistors. Thus, each of the first, second, third, and fourth anti-fuse cells 172, 174, 176, 178 is a 3T cell configuration. Although the anti-fuse cell array 170 has a first row including the first anti-fuse cell 172 and the second anti-fuse cell 174, and a second row arranged along the Y-direction relative to the first row and including the third anti-fuse cell 176 and the fourth anti-fuse cell 178, greater or fewer anti-fuse cells may be included in two or more cell rows, or in a single row along the X-direction. Moreover, the first anti-fuse cell 172, the second anti-fuse cell 174, the third anti-fuse cell 176, and the fourth anti-fuse cell 178 can be in the form of n-type or p-type transistors.

The first, second, third, and fourth anti-fuse cells 172, 174, 176, 178 each respectively include two word line transistors and a select line transistor. A first word line 180 (WLₙ) is connected to gate terminals of word line transistors 188, 190 of the first and third anti-fuse cells 172, 176, and a second word line 182 (WLₙ₊₁) is connected to gate terminals of word line transistors 192, 194 of the second and fourth anti-fuse cells 174, 178. A third word line 184 (WLₖ) is connected to gate terminals of word line transistors 196, 198 of the first and third anti-fuse cells 172, 176, and a fourth word line 186 (WLₖ₊₁) is connected to gate terminals of word line transistors 200, 202 of the second and fourth anti-fuse cells 174,178.

A first select line 204 (SLₘ) is connected to gate terminals of select line transistors 208, 210 of the first and second anti-fuse cells 172, 174, and a second select line 206 (SLₘ₊₁) is connected to gate terminals of select line transistors 212, 214 of the third and fourth anti-fuse cells 176, 178. The select lines 204, 206 bridge an isolation 216 respectively between the first anti-fuse cell 172 and the second anti-fuse cell 174 and between the third anti-fuse cell 176 and the fourth anti-fuse cell 178. A source or drain terminal of the word line transistors 196, 200, 198, 202 of each of the first, second, third, and fourth anti-fuse cells are connected to a bit line 218 (BLₘ). Thus, each of the first, second, third and fourth anti-fuse cells includes a select line transistor and a word line transistor sharing the bit line 218. FIG. 14C illustrates the anti-fuse array of FIG. 14B with portions of the select line transistors 208, 210, 212, and 214 exhibiting a state of resistance.

FIG. 14D illustrates the array of FIG. 14B with the first anti-fuse cell 172 designated as selected and the fourth anti-fuse cell 178 designated as unselected, according to an embodiment. FIG. 14E illustrates an embodiment of a process of programming a bit in the first anti-fuse cell 172 (selecting the first anti-fuse cell 172 for programming), according to an embodiment. A programming voltage (e.g., 3 V) is applied at the first select line 204 to the first select line transistor 208, a lower voltage (e.g., 1.2 V) is applied to both the first and third word lines 180, 184, and a reference voltage (e.g., 0 V) is applied at the bit line 218. The fourth anti-fuse cell 178 is unselected by a floating voltage at the second select line 206 and applying no voltage to the second and fourth word lines 182, 186. A difference between the voltage applied at the first select line 204 and the reference voltage produces an electric field across a gate dielectric layer of the first select line transistor 208. The electric field is sufficiently large to sustainably alter (e.g., break down or fuse 211) the gate dielectric layer of the first select line transistor 208, thereby decreasing the resistance of the gate dielectric layer and programming the data bit(s) in the first select line transistor.

FIG. 14F illustrates an embodiment of a process of reading a bit from the first anti-fuse cell 172 (selecting the first anti-fuse cell 172 for reading). A read voltage (e.g., 0.8 V) is applied at the first select line 204 to the first select line transistor 208, a voltage (e.g., 0.8 V) is applied to both the first and third word lines 180, 184, and a reference voltage (e.g., 0 V) is applied at the bit line 218. The fourth anti-fuse cell 178 is unselected by a floating voltage at the second select line 206 and applying no voltage to the second and fourth word lines 182, 186. The difference between the read voltage and the reference voltage creates an electric field 213 across the dielectric semiconductor layer of the first select line transistor 208. The electric field is sufficiently small to avoid sustainably altering the gate dielectric layer of the word line transistors 188, 196 but large enough to generate a read current that flows therethrough. The read current flows through the bit line 218 and is sensed by a sense amplifier (not shown) connected to the bit line to read the bit(s) stored within the first select line transistor 208.

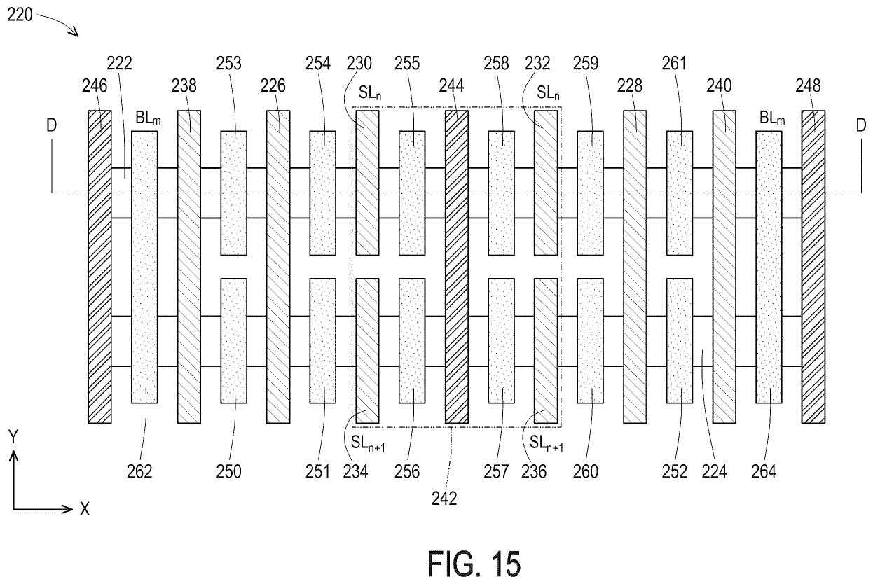

FIGS. 15-17 illustrate various views of a semiconductor device 220 including a circuit shown in FIG. 14B, according to an embodiment. FIG. 15 illustrates a plan view of the device 220 including a first common active region 222 and a second common active region 224 each extending in the X-direction. The first common active region 222 is shared by the first and second anti-fuse cells 172, 174 and the second common active region 224 is shared by the third and fourth anti-fuse cells 176, 178 shown in FIG. 14B. First and second gate lines 226, 228 extend in the Y-direction and intersect both the first and second common active regions 222, 224. The first gate line 226 corresponds to the first word line 180 (WLₙ) and the second gate line 228 corresponds to the second word line 182 (WLₙ₊₁) shown in FIG. 14B.

Third and fourth gate lines 230, 232 each extend in the Y-direction and intersect the first common active region 222. The third gate line 230 intersects the first common active region 222 between the first and second gate lines 226, 228 and the fourth gate line 232 intersects the first common active region 222 between the second and third gate lines 228, 230. The third and fourth gate lines 230, 232 do not intersect the second common active region 224. The third and fourth gate lines 230, 232 together correspond to the first select line 204 (SLₘ) shown in FIG. 14B through an electrical connection between third and fourth gate lines 230, 232, which is not shown in FIG. 15 to simplify the illustration.

Fifth and sixth gate lines 234, 236 extend in the Y-direction and intersect the second common active region 224. The fifth gate line 234 is between the first and second gate lines 226, 228 and is in alignment with the third gate line 230. The sixth gate line 236 is between the fifth and second gate lines 228, 234 and is in alignment with the fourth gate line 232. The fifth and sixth gate lines 234, 236 do not intersect the first common active region 222. The fifth and sixth gate lines 234, 236 together correspond to the second select line 206 (SLₘ₊₁) shown in FIG. 14B, through an electrical connection between fifth and sixth gate lines 234, 236, which is not shown in FIG. 15 to simplify the illustration.

The device 220 includes a seventh gate line 238 and an eighth gate line 240 that extend in the Y-direction and intersect both the first and second common active regions 222, 224. The first and second gate lines 226,228 are between the seventh and eighth gate lines 238, 240. The seventh gate line 238 corresponds to the third word line 180 (WLₖ) and the eighth gate line 240 corresponds to the fourth word line 182 (WLₖ₊₁) shown in FIG. 14B.

The device 220 includes a region 242 bounded by the dashed box which surrounds the third, fourth, fifth, and sixth gate lines 230, 232, 234, 236, where the third, fourth, fifth, and sixth gate lines 230, 232, 234, 236 include channel regions having a focused anti-fuse structure as described below. The device 220 includes a plural dielectric sacrificial gate line 244. The plural dielectric sacrificial gate line 244 extends in the Y-direction and intersects the first common active region 222 between the third and fourth gate lines 230, 232 and intersects the second common active region 224 between the fifth and sixth gate lines 234, 236.

The device 220 further includes isolating structures 246, 248, which extend in the Y-direction and intersect the first and second common active regions 222, 224. The seventh and eighth gate lines 238, 240 are between the isolating structures 246, 248. The isolating structure 246, 248 can each independently have the structure of the first sacrificial gate line 126 shown in FIG. 10A, a PODE, a polysilicon layer, the structure of the plural dielectric sacrificial gate line 244, or any other useful isolating structure.

The device 220 further includes a first metal over the diffusion line 253 and a second metal over the diffusion line 261 which extend in the Y-direction and contact the first common active region 222, and a third metal over the diffusion line 250 and a fourth metal over the diffusion line 252 respectively aligned with the first and second metal over diffusion lines and contacting the second common active region 224. The first and second gate lines 226, 228 are between the third and fourth metal over the diffusion lines 253, 261 and between the third and fourth metal over the diffusion lines 250, 252. The device 220 further includes a fifth metal over the diffusion line 254, a sixth metal over the diffusion line 259, a seventh metal over the diffusion line 255, and an eighth metal over the diffusion line 258 that each extend in the Y-direction and contact the first common active region 222. The device 220 further includes a ninth metal over the diffusion line 251, a tenth metal over the diffusion line 260, an eleventh metal over the diffusion line 256, and a twelfth metal over the diffusion line 257 that each extend in the Y-direction and contact the second common active region 224. The device 220 further includes a thirteenth and fourteenth metal over the diffusion lines 262, 264 that each extend in the Y-direction and contact both the first and second common active regions 222, 224 and are connected to the bit line 218 shown in FIG. 14B.

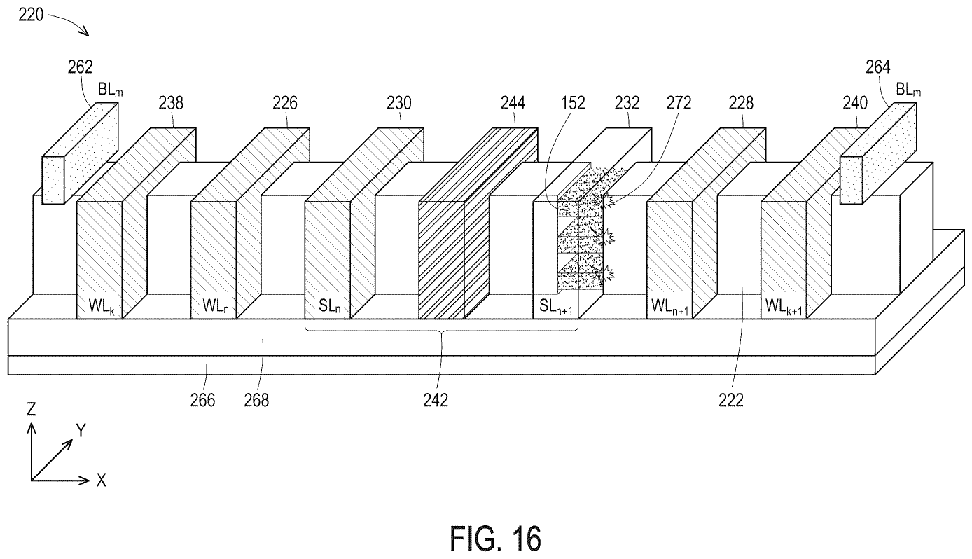

FIG. 16 illustrates a partial perspective view of the device 220 shown in FIG. 15. The device includes a substrate 266 and an isolation region 268 disposed over the substrate. The first and second common active regions 222, 224 are disposed over the substrate and protrude above the isolation region 268 in the Z-direction. Only the first common active region 222 is shown in FIG. 16. The first gate line 226, second gate line 228, third gate line 230, fourth gate line 232, seventh gate line 238, and eighth gate line 240 are shown intersecting the first common active region 222. The plural dielectric sacrificial gate line 244 intersects the first common active region 222 between the third and fourth gate lines 230, 232. The first common active region 222 includes the source and drain terminals of the word line transistors 188, 196 and the select line transistor 208 of the first anti-fuse cell 172 and the source and drain terminals of the word line transistors 192, 200 and the select line transistor 210 of the second anti-fuse cell 174 shown in FIG. 14B.

A region 242 including the third and fourth gate lines 230, 232 and the plural dielectric sacrificial gate line 244 is shown. The fourth gate line 232 is illustrated transparently to show area 272 and semiconductor layers 152. In area 272, a gate dielectric material of the gate line can transform from an anti-fuse to fuse structure upon application of a sufficient voltage. In some embodiments, the semiconductor layers 152 extend the length of the first common active region through channel regions of the first, second, third, fourth, seventh, and eighth gate lines 226, 228, 230, 232, 238, 240 and through sections of the first common active region 222 between the gate lines. In alternate embodiments, semiconductor layers reside in channel regions of the gate lines, but no semiconductor layers reside in sections of a common active region between the channel regions, and the common active region includes epitaxially formed source/drain structures between channel regions of gate lines without the semiconductor layers.

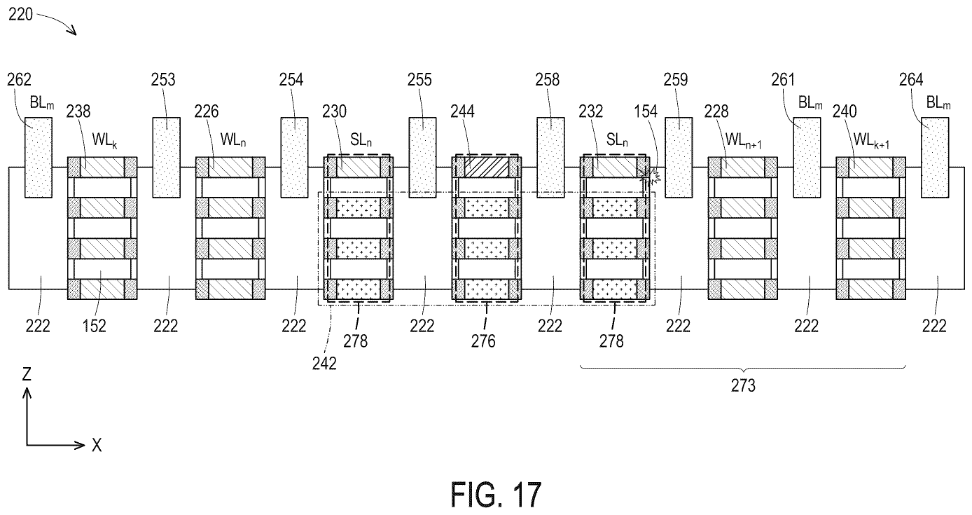

FIG. 17 illustrates a partial cross-section of the device 220 taken along taken along the X-direction at D-D in FIG. 15. A broken line box 274 surrounds a channel region of the second gate line 228 and includes the structure of the channel region shown in FIG. 13B. The channel regions of the first, seventh, and eighth gate lines 226, 238, 240 also have the structure of the channel region shown in FIG. 13B. A broken line box 276 surrounds a channel region of the plural dielectric sacrificial gate line 146 and includes the structure of the channel region shown in FIG. 13C. A broken line box 278 surrounds a channel region of the third and fourth gate lines 230, 232 and includes the structure of the channel region shown in FIG. 13D. The gate dielectric layer 116 in FIG. 13D is configured to function as an anti-fuse structure convertible to a fuse structure through application of a sufficient voltage to the third and fourth gate lines 138, 140. Given that the anti-fuse structure is concentrated or focused at a single level of the third and fourth gate lines 230, 232 control of current through the anti-fuse structure can be more easily controlled relative to gate lines including plural anti-fuse structures. By implementing a sacrificial gate line and gate lines including focused anti-fuse structures, circuitry operating under high voltage can exhibit high bias immunity, and a breakdown point of an anti-fuse structure can be controlled to improve variation in on-cell current. In other embodiments, the channel region in box 278 has the structure shown in 21C described below.

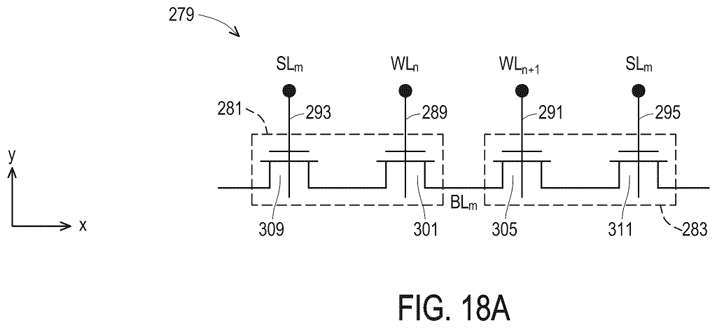

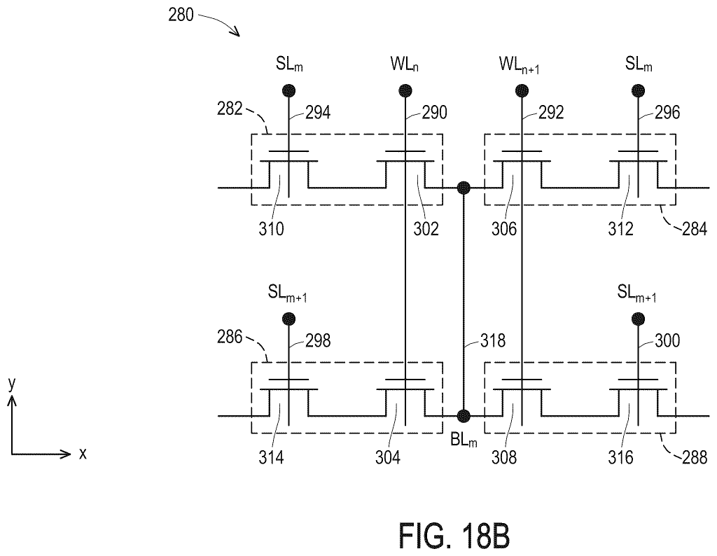

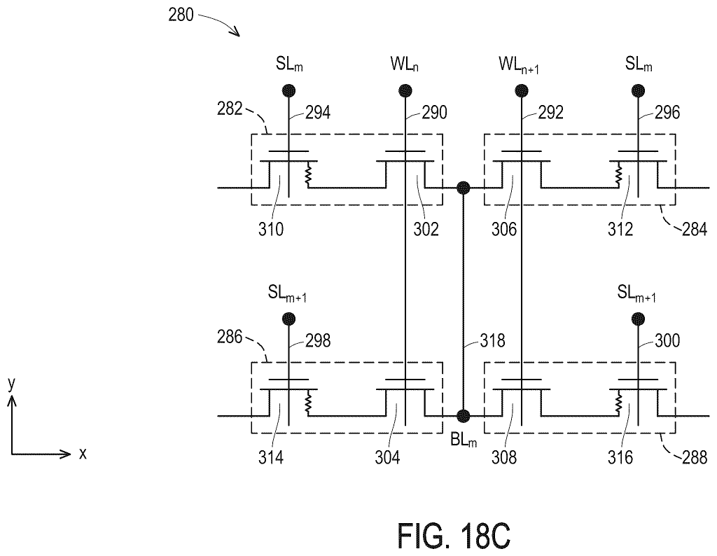

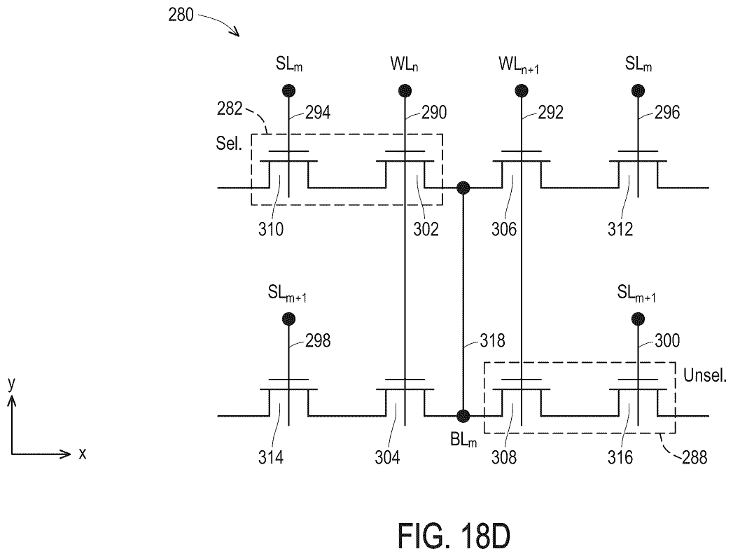

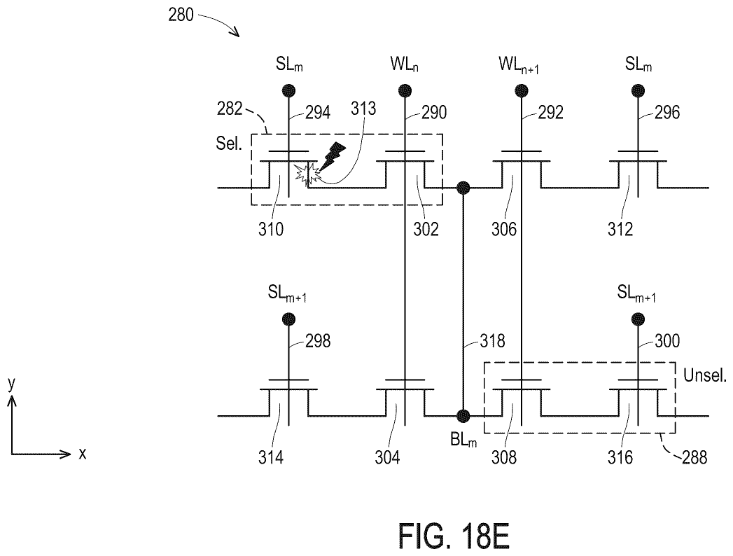

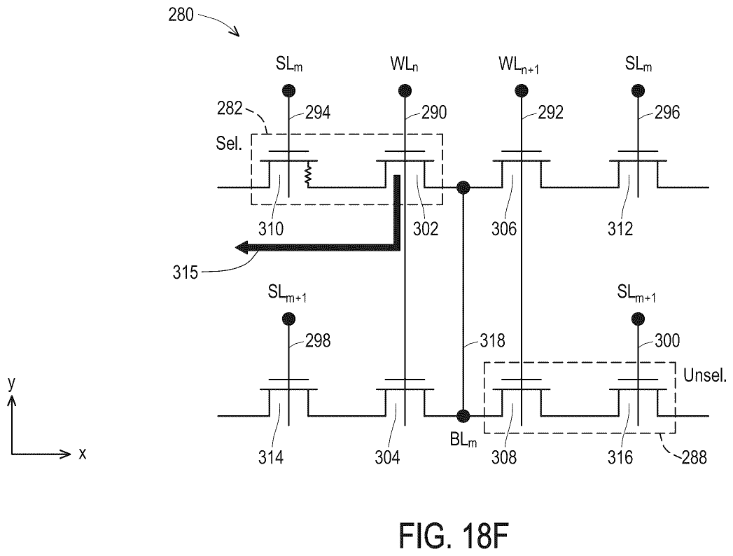

FIG. 18A illustrates an anti-fuse cell array 279 in accordance with some embodiments of the present disclosure. The anti-fuse cell array 279 includes a first anti-fuse cell 281 and a second anti-fuse cell 283 (both shown within dashed boxes in FIG. 18A). In some embodiments, and as shown, both of the first and second anti-fuse cells 281, 283 include two transistors. Thus, both of the first and second anti-fuse cells 281, 283 are in a 2T cell configuration. Although the anti-fuse cell array 279 has a row including the first anti-fuse cell 281 and the second anti-fuse cell 283, greater or fewer anti-fuse cells may be included in two or more cell rows, and/or in the same row along the X-direction. Moreover, the first anti-fuse cell 281 and the second anti-fuse cell 283 can be in the form of n-type or p-type transistors. The first and second anti-fuse cells 281, 283 each include a word line transistor and a select line transistor. A first word line 289 (WLₙ) is connected to a gate terminal of word line transistor 301 of the first anti-fuse cell 281, and a second word line 291 (WLₙ₊₁) is connected to a gate terminal of word line transistors 305 of the second anti-fuse cell 283. A first select line 293 (SLₘ) is connected to a gate terminal of select line transistor 309 of the first anti-fuse cell 282, and a second select line 295 (SLₘ) is connected to a gate terminal of a select line transistor 311 of the second anti-fuse cell 283. A bit line 317 (BLₘ) is connected to a source/drain structures between the first and second word line transistors 301, 305. Thus, the first and second anti-fuse cells each include a word line transistor sharing the bit line 317.

FIG. 18B illustrates an anti-fuse cell array 280 in accordance with some embodiments of the present disclosure. The anti-fuse cell array 280 includes a first anti-fuse cell 282, a second anti-fuse cell 284, a third anti-fuse cell 286, and a fourth anti-fuse cell 288 (each shown within dashed boxes in FIG. 18B). In some embodiments, and as shown, each of the first, second, third, and fourth anti-fuse cells 282, 284, 286, 288 includes two transistors. Thus, each of the first, second, third, and fourth anti-fuse cells 282, 284, 286, 288 is a 2T cell configuration.

Although the anti-fuse cell array 280 has a first row including the first anti-fuse cell 282 and the second anti-fuse cell 284, and a second row arranged along the Y-direction relative to the first row and including the third anti-fuse cell 286 and the fourth anti-fuse cell 288, greater or fewer anti-fuse cells may be included in two or more cell rows, and/or in a same row along the X-direction. Moreover, the first anti-fuse cell 282, the second anti-fuse cell 284, the third anti-fuse cell 286, and the fourth anti-fuse cell 288 can be in the form of n-type or p-type transistors.

The first, second, third, and fourth anti-fuse cells 282, 284, 286, 288 each respectively include a word line transistor and a select line transistor. A first word line 290 (WLₙ) is connected to gate terminals of word line transistors 302, 304 of the first and third anti-fuse cells 282, 286, and a second word line 292 (WLₙ₊₁) is connected to gate terminals of word line transistors 306, 308 of the second and fourth anti-fuse cells 284, 288. A first select line 294 (SLₘ) is connected to a gate terminal of select line transistor 310 of the first anti-fuse cell 282, a second select line 296 (SLₘ) is connected to a gate terminal of a select line transistor 312 of the second anti-fuse cell 284, a third select line 298 (SLₘ₊₁) is connected to a gate terminal of a select line transistor 314 of the third anti-fuse cell 286, and a fourth select line 300 (SLₘ₊₁) is connected to a gate terminal of a select line transistor 314 of the fourth anti-fuse cell 288. A bit line 318 (BLₘ) is connected to a source/drain structures between the first and second word line transistors 302, 306 and between the third and fourth word line transistors 304, 308. Thus, each of the first, second, third, and fourth anti-fuse cells includes a word line transistor sharing the bit line 318.

FIG. 18C illustrates portions of the select line transistors 310, 312, 314, and 316 exhibiting a state of resistance.

FIG. 18D illustrates the array of FIG. 18B with the first anti-fuse cell 282 designated as selected and the fourth anti-fuse cell 288 designated as unselected, according to an embodiment. FIG. 18E illustrates an embodiment of a process of programming a bit in the first anti-fuse cell 282 (selecting the first anti-fuse cell 282 for programming), according to an embodiment. A programming voltage (e.g., 3 V) is applied at the first select line 294 to the first select line transistor 310, a lower voltage (e.g., 1.2 V) is applied to the first word line 290, and a reference voltage (e.g., 0 V) is applied at the bit line 318. The fourth anti-fuse cell 288 is unselected by a floating voltage at the fourth select line 300 and applying no voltage to the second word line 292. A difference between the voltage applied at the first select line 294 and the reference voltage produces an electric field across a gate dielectric layer of the first select line transistor 310. The electric field is sufficiently large to sustainably alter (e.g., break down or fuse 313) the gate dielectric layer of the first select line transistor 310, thereby decreasing the resistance of the gate dielectric layer and programming the data bit(s) in the first select line transistor.

FIG. 18F illustrates an embodiment of a process of reading a bit from the first anti-fuse cell 282 (selecting the first anti-fuse cell 282 for reading). A read voltage (e.g., 0.8 V) is applied at the first select line 294 to the first select line transistor 310, a voltage (e.g., 0.8 V) is applied to both the first word line 290, and a reference voltage (e.g., 0 V) is applied at the bit line 318. The fourth anti-fuse 288 is unselected by a floating voltage at the fourth select line 300 and applying no voltage to the fourth word line 292. The difference between the read voltage and the reference voltage creates an electric field 315 across the dielectric semiconductor layer of the first select line transistor 302. The electric field is sufficiently small to avoid sustainably altering the gate dielectric layer of the first word line transistor 310 but large enough to generate a read current that flows therethrough. The read current flows through the bit line 318 and is sensed by a sense amplifier (not shown) connected to the bit line to read the bit(s) stored within the first select line transistor 302.

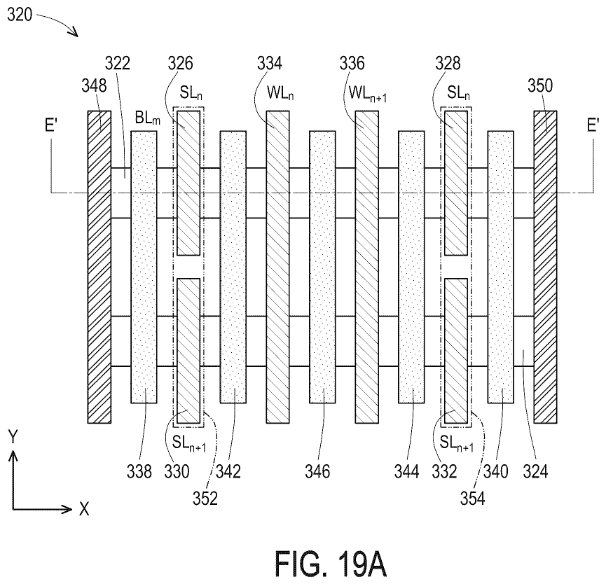

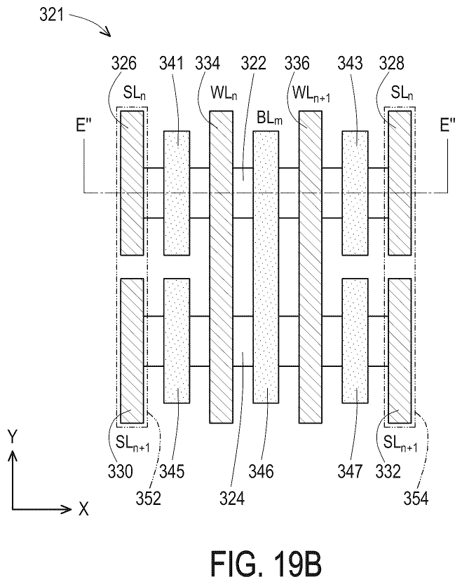

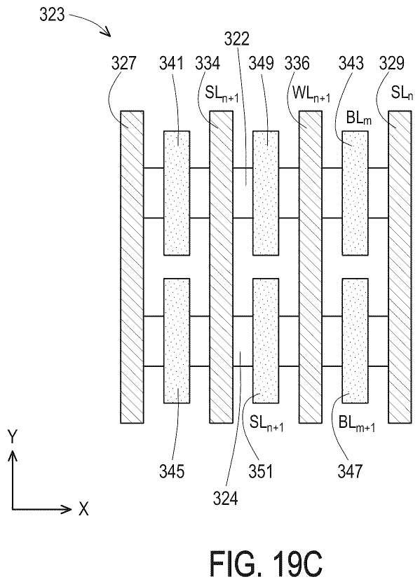

FIG. 19A illustrates a semiconductor device 320 including a circuit wiring shown in FIG. 18B, according to an embodiment. FIG. 19A illustrates a plan view of the device 320 including a first common active region 322 and a second common active region 324 each extending in the X-direction. The first common active region 322 is shared by the first and second anti-fuse cells 282, 284 and the second common active region 324 is shared by the third and fourth anti-fuse cells 286, 288 shown in FIG. 18B. First and second gate lines 326, 328 extend in the Y-direction and intersect the first common active region 322 but do not intersect the second common active region 324. The first gate line 326 corresponds to first select line 294 (SLₘ) and second gate line 328 corresponds to the second select line 296 (SLₘ) shown in FIG. 18B. Third and fourth lines 330, 332 extend in the Y-direction and intersect the second common active region 324 but do not intersect the first common active region 322. The third gate line 330 is in alignment with the first gate line 326 and the fourth gate line 332 is in alignment with the second gate line 328. The third gate line 330 corresponds to third select line 298 (SLₘ₊₁) and fourth gate line 332 corresponds to the fourth select line 300 (SLₘ₊₁) shown in FIG. 18B.

Fifth and sixth gate lines 334, 336 extend in the Y-direction and intersect both the first and second common action regions. The fifth gate line 334 intersects the first common active region 322 between the first and second gate lines 326, 328 and intersects the second common active region 324 between the third and fourth gate lines 330, 332. The sixth gate line 336 intersects the first common active region 322 between the second and fifth lines 328, 334 and intersects the second common active region 324 between the fourth and fifth lines 332,334. The fifth gate line 334 corresponds to the first word line 290 (WLₙ) and the sixth gate line 336 corresponds to the second word line 292 (WLₙ₊₁) shown in FIG. 18B.

The device 320 further includes a first metal over diffusion line 338 and a second metal over diffusion line 340 which extend in the Y-direction and contact the first and second common active regions 322, 324. The first, second, third, fourth, fifth, and sixth gate lines 326, 328, 330, 332, 334, 336 are between the first and second metal over diffusion lines 338, 340. Third and fourth metal over diffusion lines 342, 344 extend in the Y-direction and contact the first and second common active regions 322, 324. The third metal over diffusion layer 342 intersects the first common active region 322 between the first and fifth gate lines 326, 334 and intersects the second common active region between the third and fifth gate lines 330, 334. The fourth metal over diffusion layer 344 intersects the first common active region 322 between the second and sixth gate lines 328, 336 and intersects the second common active region between the fourth and sixth gate lines 332, 336. A fifth metal over diffusion layer 346 intersects the first and second common active region 322, 324 between the fifth and sixth gate lines 334, 336. The fifth metal over diffusion layer 346 corresponds to the bit line (BLₘ) shown in FIG. 18B.

The device 320 further includes isolating structures 348, 350 that extend in the Y-direction and intersect the first and second common active regions 322, 324. The isolating structures 348, 350 can each independently have the structure of the first sacrificial gate line 126 shown in FIG. 10A, a PODE, the structure of the plural dielectric sacrificial gate line shown in FIG. 13A, or any other useful isolating structure.

The device 220 includes region 352 bounded by the dashed box that surrounds the first and third gate lines 326,330 and region 354 bounded by the dashed box that surrounds the second and fourth gate lines 328, 332 where first, second, third, and fourth gate lines include channel regions having a focused anti-fuse structure as described below.

FIG. 19B illustrates plan view of another embodiment of a semiconductor device 321 a first common active region 322 and a second common active region 324 each extending in the X-direction. The first common active region 322 is shared by the first and second anti-fuse cells 282, 284 and the second common active region 324 is shared by the third and fourth anti-fuse cells 286, 288 shown in FIG. 18B. First and second gate lines 326, 328 extend in the Y-direction and intersect the first common active region 322 but do not intersect the second common active region 324. The first gate line 326 corresponds to first select line 294 (SLₘ) and second gate line 328 corresponds to the second select line 296 (SLₘ) shown in FIG. 18B. Third and fourth lines 330, 332 extend in the Y-direction and intersect the second common active region 324 but do not intersect the first common active region 322. The third gate line 330 is in alignment with the first gate line 326 and the fourth gate line 332 is in alignment with the second gate line 328. The third gate line 330 corresponds to third select line 298 (SLₘ₊₁) and fourth gate line 332 corresponds to the fourth select line 300 (SLₘ₊₁) shown in FIG. 18B. Fifth and sixth gate lines 334, 336 extend in the Y-direction and intersect both the first and second common active regions. The fifth gate line 334 intersects the first common active region 322 between the first and second gate lines 326, 328 and intersects the second common active region 324 between the third and fourth gate lines 330, 332. The sixth gate line 336 intersects the first common active region 322 between the second and fifth lines 328, 334 and intersects the second common active region 324 between the fourth and fifth lines 332,334. The fifth gate line 334 corresponds to the first word line 290 (WLₙ) and the sixth gate line 336 corresponds to the second word line 292 (WLₙ₊₁) shown in FIG. 18B. The device 321 further includes first and second metal over diffusion lines 341, 343 that extend in the Y-direction and contact the first common active region 322 but do not contact the second common active region 324. The device 321 further includes third and fourth metal over diffusion lines 345, 347 that extend in the Y-direction and contact the second common active region 324 but do not contact the second common active region 322. A fifth metal over diffusion layer 346 corresponds to the bit line (BLₘ) shown in FIG. 18B.

FIG. 19C illustrates a plan view of a semiconductor device 323 according to some embodiments. The semiconductor device 323 includes a first common active region 322 and a second common active region 324 each extending in the X-direction. First and second gate lines 334, 336 extend in the Y-direction and intersect both the first and second common active regions 322, 324. Third and fourth gate lines 327, 329 extend in the Y-direction and intersect the first common active region 322 and the second common active region 324. The third and fourth gate lines 327, 329 can function as PODE structures. The device 321 further includes first and second metal over diffusion lines 341, 343 that extend in the Y-direction and contact the first common active region 322 but do not contact the second common active region 324. The device 321 further includes third and fourth metal over diffusion lines 345, 347 that extend in the Y-direction and contact the second common active region 324 but do not contact the second common active region 322. Fifth and sixth metal over diffusion layers 349, 351 are between the first and second gate lines 334, 336.

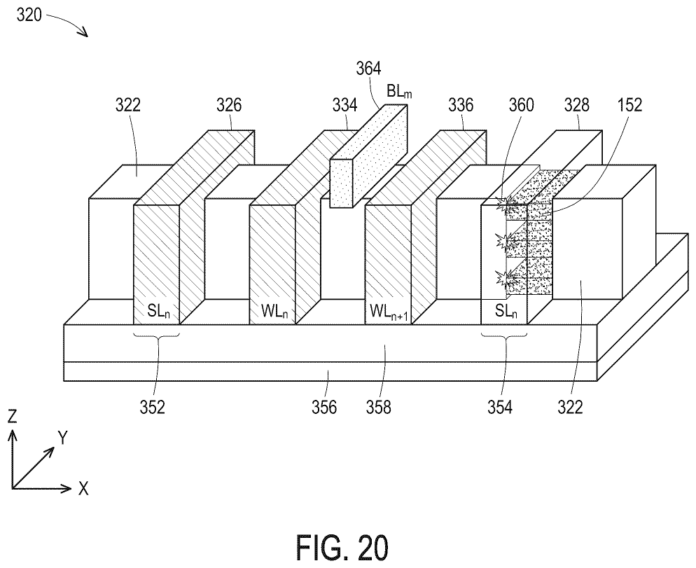

FIG. 20 illustrates a partial perspective view of the devices 320 and 321 respectively shown in FIGS. 19A-19C. The devices include a substrate 356 and an isolation region 358 disposed over the substrate. The first and second common active regions 322, 324 are disposed over the substrate and protrude above the isolation region 358 in the Z-direction. Only the first common active region 322 is shown in FIG. 20. The first gate line 326, second gate line 328, fifth gate line 334, and sixth gate line 336, are shown intersecting the first common active region 322. The second gate line 328 is illustrated transparently to show area 360 and semiconductor layers 152. The first common active region 322 includes the source and drain terminals of the word line transistors 302, 306 and the select line transistors 310, 312 of the first and second anti-fuse cell 282, 284 shown in FIG. 18B.

An area 360 is shown where a gate dielectric material of a gate line can transform from an anti-fuse to fuse structure upon application of a sufficient voltage. Semiconductor layers 152 are schematically illustrated. In some embodiments, the semiconductor layers 152 extend through sections of the first common active region between the gate lines. In alternate embodiments, semiconductor layers reside in channel regions of the gate lines, but no semiconductor layers reside in sections of a common active region between the channel regions, and the common active region includes epitaxially formed source/drain structures between channel regions of gate lines without the semiconductor layers.

FIG. 21A illustrates a partial cross-section of the devices 320 and 321 taken along the X-direction at E′-E′ in FIG. 19A and at E″-E″ in FIG. 19B, according to some embodiments. A broken line box 362 surrounds a channel region of the first gate line 326 and includes the structure of the channel region shown in FIG. 13D. The channel region of the second gate 328 also has the structure of the channel region shown in FIG. 13D. The gate dielectric layer 116 in FIG. 13D is configured to function as an anti-fuse structure convertible to a fuse structure through application of a sufficient voltage to the first and second gate lines 326, 328. Given that the anti-fuse structure can be concentrated or focused at a single level of the first and second gate lines 326, 328, control of current through the anti-fuse structure can be more easily controlled relative to gate lines including plural anti-fuse structures. A selected cell 329 has an area 327 where a gate dielectric material of a gate line can transform from an anti-fuse to fuse structure upon application of a sufficient voltage. Unselected area 331 does not have the transformed area 327. A broken line box 364 surrounds a channel region of the fifth gate line 334 and includes the structure of the channel region shown in FIG. 13B. The channel region of the sixth gate line 336 also has the structure of the channel region shown in FIG. 13B. No isolating structure is present in the array shown in FIG. 21A.

The first, second, third, and fourth gate lines 326, 328, 330, 332 can function as PODE structures. By implementing PODE in the anti-fuse regions, the overall cell area of a semiconductor device can be reduced and the total number of pins, e.g., accounting for word lines, select lines, and bit lines, can be reduced. By implementing gate lines including focused anti-fuse structures, a breakdown point of an anti-fuse structure can be controlled to improve variation in on-cell current and attenuate channel inversion generation.

FIG. 21B illustrates a partial cross-section of the device 321 taken along the X-direction at E′-E′ in FIG. 19A and at E″-E″ in FIG. 19B, according to some embodiments. A broken line box 364 surrounds a channel region of the fifth gate line 334 and includes the structure of the channel region shown in FIG. 13B. The sixth gate line also has the structure of the channel region shown in FIG. 13B. A broken line box 363 surrounds a channel region of the first gate line 326 and includes the structure of the channel region shown in shown in FIG. 21C. The second gate line 328 also includes the structure of the channel region shown in shown in FIG. 21C. FIG. 21C illustrates a focused anti-fuse structure of the first and second gate lines 326, 328. A gate structure 114 is provided around the upper semiconductor layer 152U. The gate structure 114 includes a gate dielectric layer 116, a work function layer 118, and a gate material 120. The gate dielectric layer 116 is between the gate material 120 and the semiconductor layer 152U and between the gate material 120 and the source/drain structures of the first common active region 322. The gate dielectric layer 116 is configured to function as an anti-fuse structure convertible to a fuse structure through application of a sufficient voltage to the first and second gate lines 326, 328. The second dielectric material 164 is disposed under the upper semiconductor layer 152U and between the semiconductor layers 152L below the upper semiconductor layer 152U. The second dielectric material is surrounded by a gate dielectric layer 116. Inner spacers 122 are formed on opposite sides of the gate material 120 and the second dielectric material 164 at different levels of the channel region. Given that the anti-fuse structure can be concentrated or focused at two levels of the first and second gate lines 326, 328, control of current through the anti-fuse structure can be more easily controlled relative to gate lines including more than two anti-fuse structures. In FIG. 21B, a selected cell 329 has an area 327 where a gate dielectric material of a gate line can transform from an anti-fuse to fuse structure upon application of a sufficient voltage. Unselected area 331 does not have the transformed area 327. A broken line box 364 surrounds a channel region of the fifth gate line 334 and includes the structure of the channel region shown in FIG. 13B. The channel region of the sixth gate line 336 also has the structure of the channel region shown in FIG. 13B.

The first, second, third, and fourth gate lines 326, 328, 330, 332 can function as PODE structures. By implementing the PODE structure in the anti-fuse regions, the overall cell area of a semiconductor device can be reduced and the total number of pins, e.g., accounting for word lines, select lines, and bit lines, can be reduced. By implementing gate lines including focused anti-fuse structures, a breakdown point of an anti-fuse structure can be controlled to improve the variation in on-cell current and attenuate the channel inversion generation.

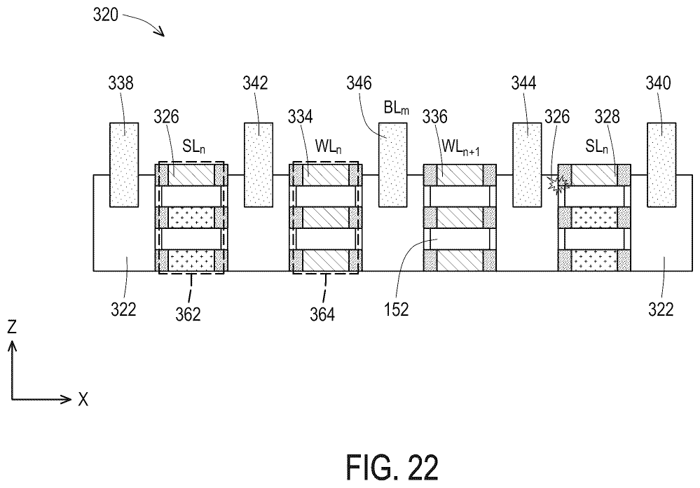

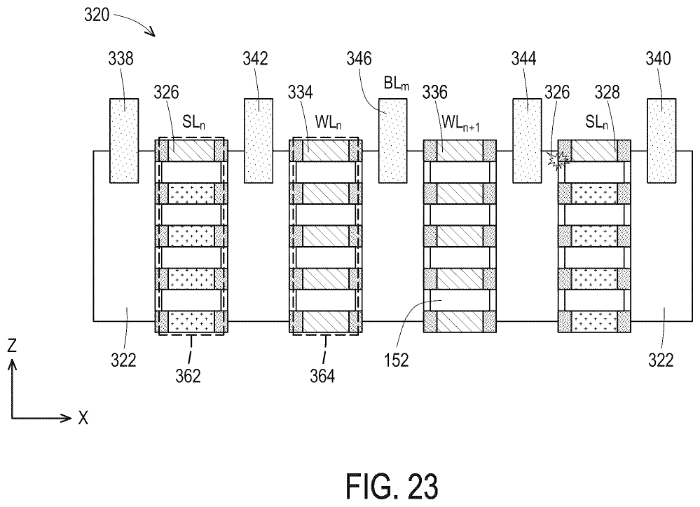

FIGS. 22 and 23 illustrate the same structure as in FIG. 21A, with the exception that the number of semiconductor layers differ from FIG. 21A. The stack of semiconductor layers 152 extending through the channel regions and first common active region in FIG. 22 has one less semiconductor layer relative to the stack of semiconductor layers shown in FIG. 21A. A stack of semiconductor layers 152 extending through channel regions and first common active region in FIG. 23 has one greater semiconductor layer relative to the stack semiconductor layers shown in FIG. 21. Any embodiment in the present disclosure can include a stack of semiconductor layers having any useful number of semiconductor layers, e.g., 1, 2, 3, 4, 5, 6, 7, 8, 9, 10, 11, 12, 13, 14, 15, or any further useful number of semiconductor layers.

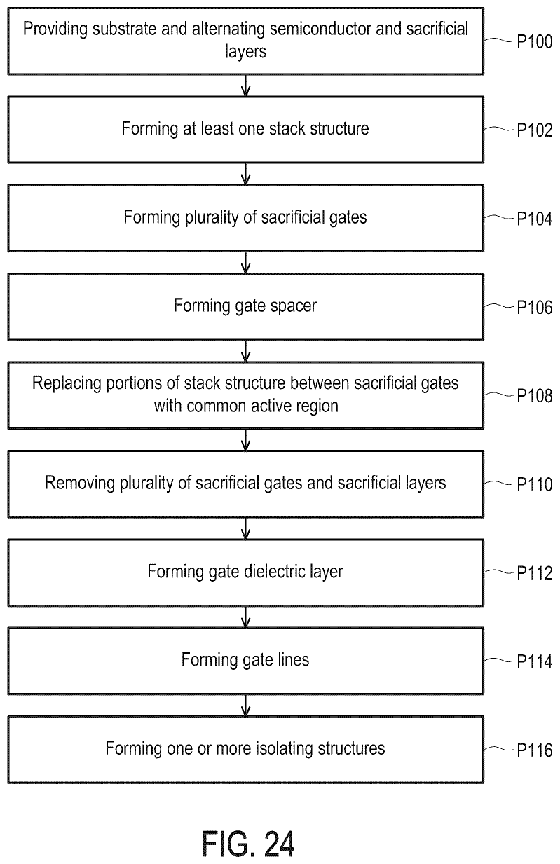

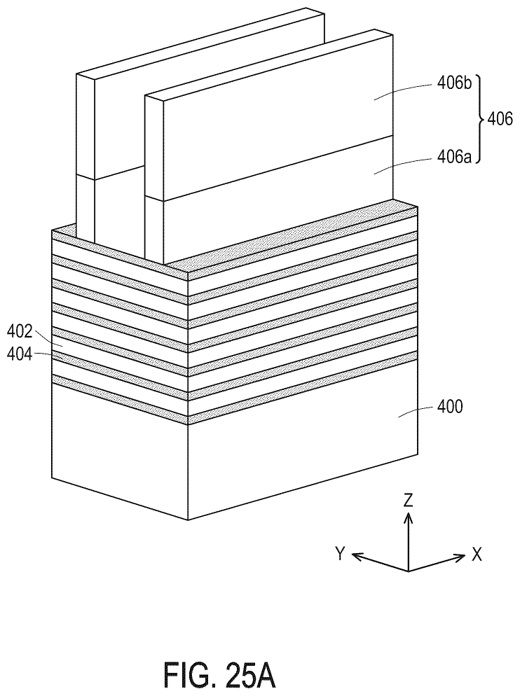

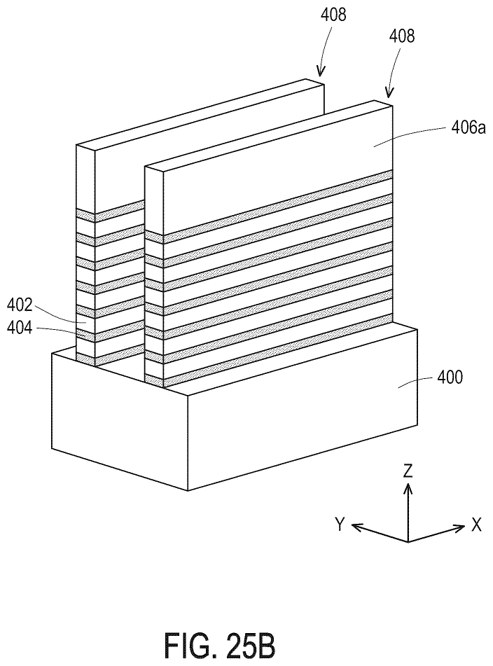

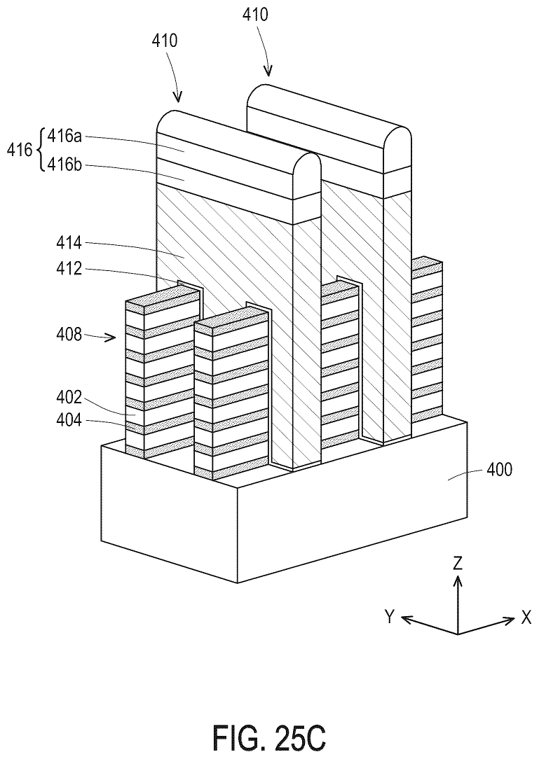

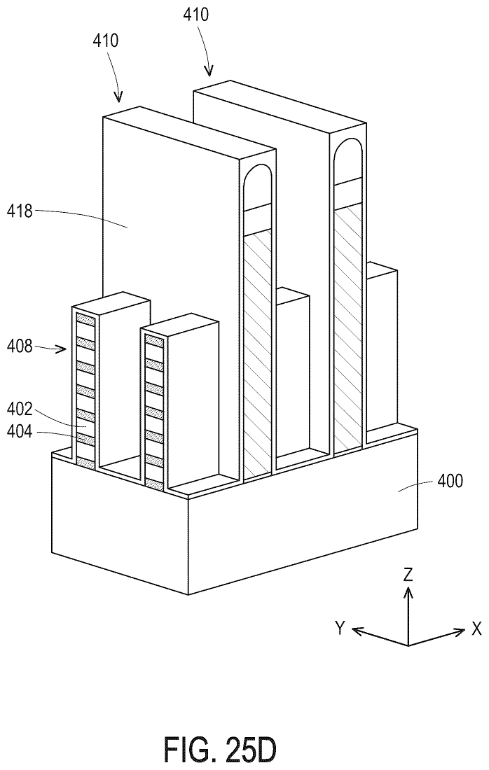

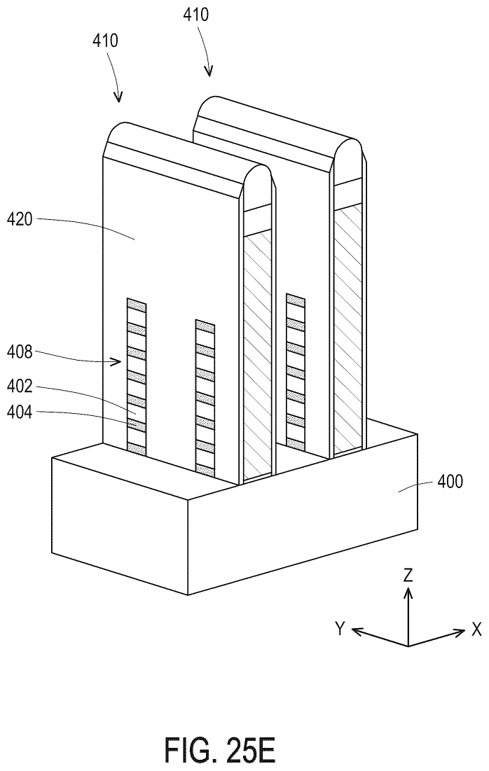

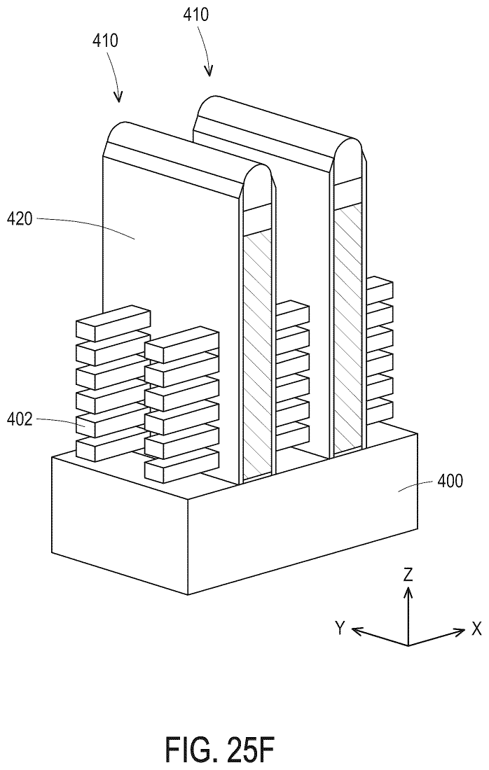

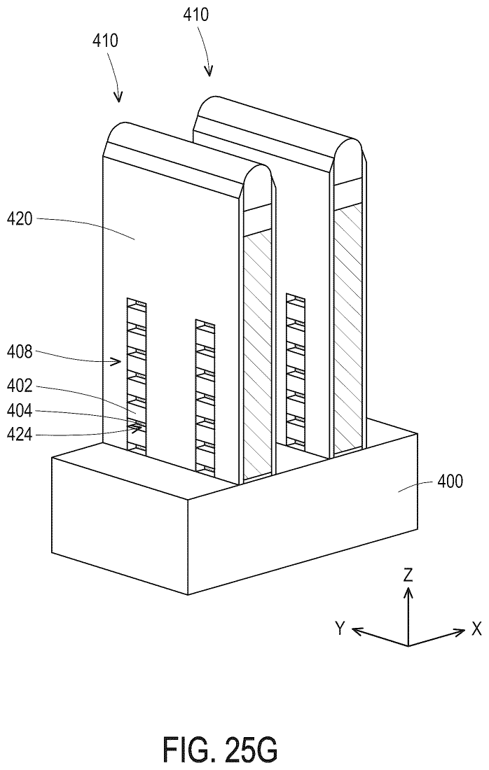

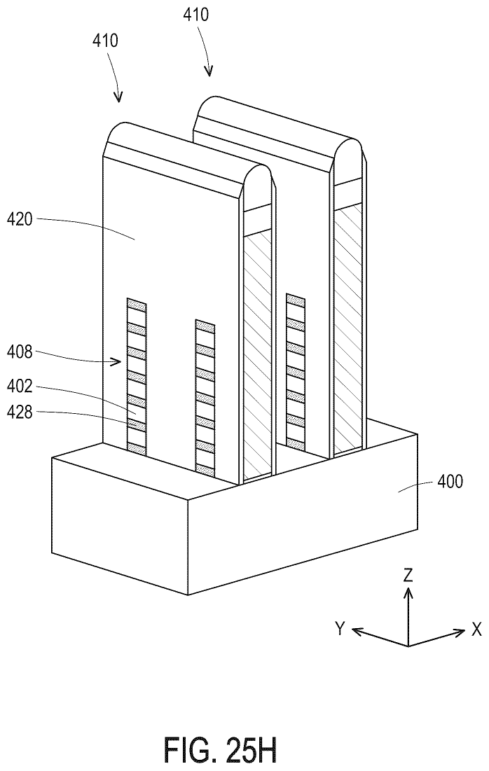

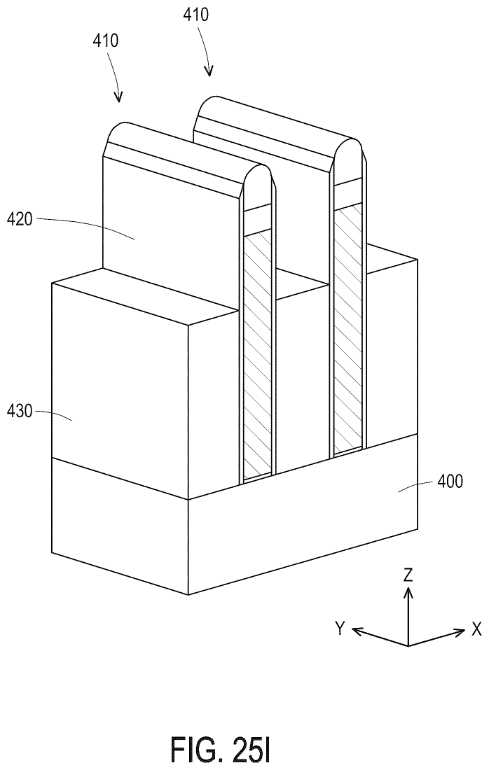

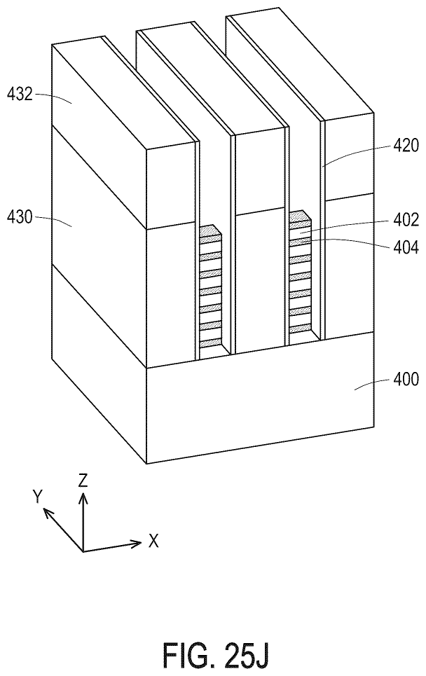

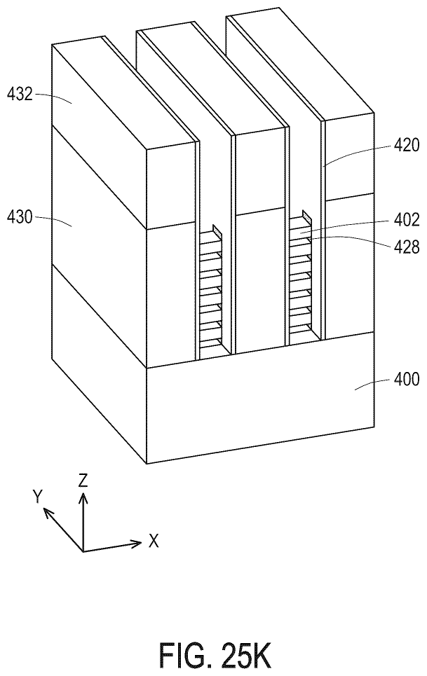

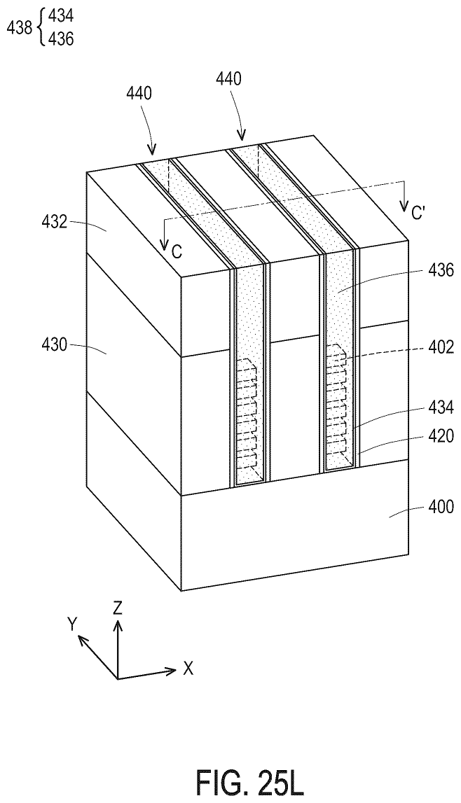

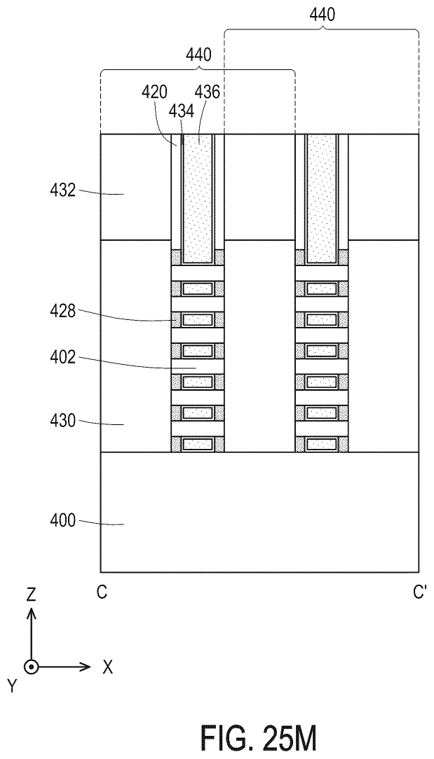

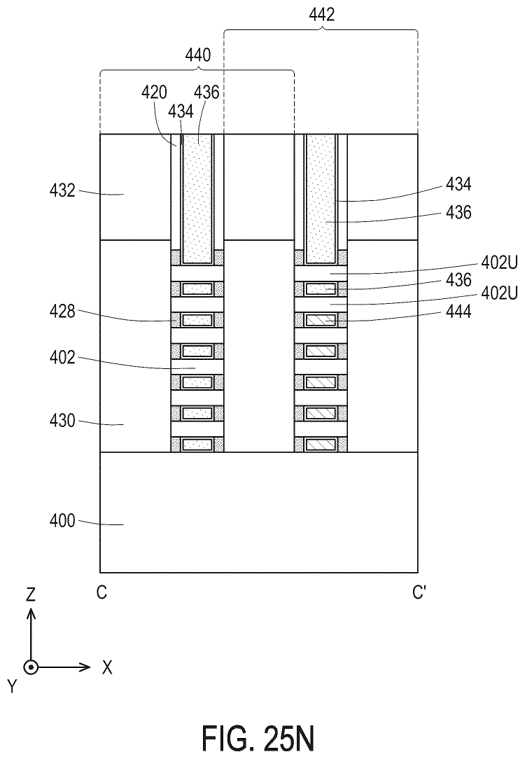

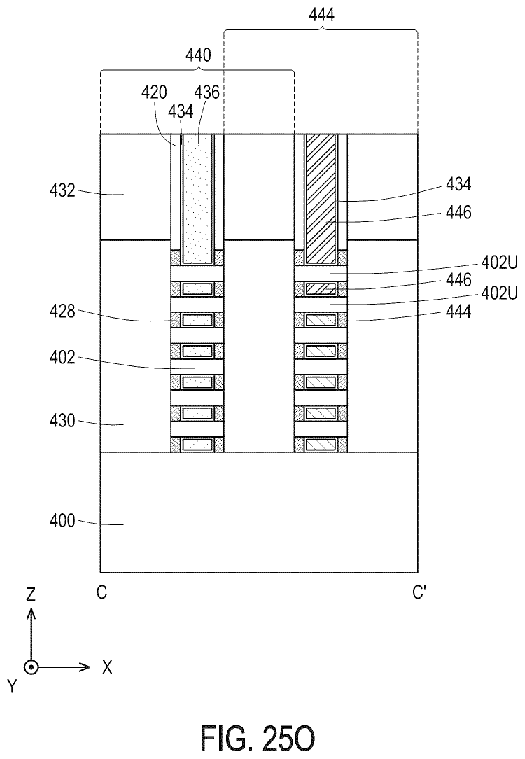

FIG. 24 is a flow diagram illustrating a method for forming transistors and embedded insulating structures according to some embodiments. FIG. 25A through FIG. 25O are schematic cross-sectional views illustrating structures at various stages during embodiments of processes for forming a semiconductor device. FIG. 25M is a cross-sectional view along a line C-C′ shown in FIG. 25L. The transistors (e.g., transistors 440 and 442 as shown in FIG. 25M-25O) can be word line transistors or select line transistors.

Referring to FIG. 24 and FIG. 25A, a process P100 of forming semiconductor layers 402, sacrificial layers 404, and hard mask structures 406 on a substrate 400 is performed. Regions of isolation, such as those formed by an STI process and including one or more insulating materials, can be provided on the surface of the substrate. To simplify the illustrations, isolation regions are omitted. The substrate 400 can be a semiconductor wafer or a semiconductor-on-insulator (SOI) wafer. The semiconductor layers 402 and the sacrificial layers 404 are alternately formed on the substrate 400, to form a stack structure on the substrate 400. In some embodiments, the semiconductor layers 402 and the sacrificial layers 404 are made of different semiconductor materials, such that the semiconductor layers 402 could have a sufficient etching selectivity with respect to the sacrificial layers 404. For instance, the semiconductor layers 402 are made of silicon, whereas the sacrificial layers 404 are made of silicon germanium. In addition, a method for forming the semiconductor layers 402 and the sacrificial layers 404 may include one or more deposition processes such as epitaxial processes. On the other hand, the hard mask structures 406 are formed on the stacking structure. In some embodiments, the hard mask structures 406 are arranged along the Y-direction and extend along the X-direction. In addition, in some embodiments, each hard mask structure 406 includes a hard mask layer 406a and a hard mask layer 406b formed over the hard mask layer 406a. The hard mask layers 406a, 406b may be made of different insulating materials. For instance, materials of the hard mask layers 406a, 406b may be selected from a group consisting of silicon oxide, silicon nitride, silicon oxynitride and the like. A method for forming the hard mask structures 406 may include one or more deposition process (e.g., chemical vapor deposition (CVD) process) and a self-aligned multiple patterning process (e.g., a self-aligned double patterning (SADP) process or a self-aligned quadruple patterning (SAQP) process).

Referring to FIG. 24 and FIG. 25B, a process P102 is performed to form stack structures of the semiconductor layers 402 and the sacrificial layers 404 by patterning into stacks 408 using the hard mask structures 406 as masks in some embodiments. In those embodiments where the hard mask structures 406 are arranged along the Y-direction and extend along the X-direction, the formed stacks 408 are also arranged along the Y-direction Y and extend along the X-direction. A method for patterning the stack structure to form the stacks 408 may include an etching process, such as an anisotropic etching process. The etching process may be stopped when a top surface of the substrate 400 is exposed, or a top portion of the substrate may be removed during the etching process. In some forms depositing a stack structure includes deposition of layers and etching of the layers into the stack structure. In some embodiments, the hard mask layers 406b of the hard mask structures 406 are removed during the etching process.

Referring to FIG. 24 and FIG. 25C, a process P104 is performed to form sacrificial gate structures 410 on the substrate 400 in some embodiments. An extending direction of the sacrificial gate structures 410 intersects with an extending direction of the stack structures 408, and the sacrificial gate structures 410 cover portions of the stack structures 408 that are overlapped with the sacrificial gate structures 410. In those embodiments where the stack structures 408 are arranged along the Y-direction and extend along X-direction, the sacrificial gate structures 410 are arranged along the X-direction and extend along the Y-direction. In some embodiments, each sacrificial gate structure 410 includes a sacrificial gate dielectric layer 412 and a sacrificial gate electrode 414. The sacrificial gate dielectric layer 412 is conformally formed on the substrate 400 and the stack structures 408, whereas the sacrificial gate electrodes 414 cover the sacrificial gate dielectric layer 412, and are formed to a height greater than a height of the stack structures 408. In some embodiments, each sacrificial gate structure 410 further includes a capping structure 416 lying on the sacrificial gate electrode 414. The capping structure 416 may include a capping layer 416a and a capping layer 416b lying above the capping layer 416a. In some embodiments, the capping layer 416b has rounded top corners. Materials of the sacrificial gate dielectric layer 412, the capping layer 416a, and the capping layer 416b may respectively include silicon oxide, silicon nitride, silicon oxynitride, the like or combinations thereof, whereas a material of the sacrificial gate electrode 414 may include polysilicon. In addition, methods for forming the sacrificial gate dielectric layer 412, the capping layers 416a, 416b and the sacrificial gate electrode 314 may respectively include a deposition process, such as a CVD process or an atomic layer deposition (ALD) process.

Referring to FIG. 24 and FIG. 25D, a process P106 is performed to form a gate spacer layer 418 in some embodiments. In some embodiments, the gate spacer layer 418 is globally formed over the structure as shown in FIG. 25D. The substrate 400, the stack structures 408 and the sacrificial gate structures 410 may be conformally covered by the gate spacer layer 418. A material of the gate spacer layer 418 may include silicon oxide, silicon nitride, silicon carbide, silicon oxynitride, SiCN, silicon oxycarbide, SiOCN, the like or combinations thereof, and a method for forming the gate spacer layer 418 may include a deposition process, such as a CVD process or an ALD process.

Referring to FIG. 24 and FIG. 25E, a process P108 of replacing portions of stack structures between sacrificial gates with a common active region is initiated in some embodiments. Some portions of the stack structures 408 and the gate spacer layer 418 are removed. In some embodiments, portions of the gate spacer layer 418 covering the sidewalls of the sacrificial gate structures 410 become gate spacers 420. On the other hand, other portions of the gate spacer layer 418 are removed, and portions of the stack structures 408 not covered by the sacrificial gate structures 410 and the gate spacers 420 are accordingly exposed. Thereafter, the exposed portions of the stack structures 408 are removed, and portions of the stack structures 408 covered by the gate spacers 420 and the sacrificial gate structures 410 remain. In another embodiment shown in FIG. 25F, the portions of the stack structures 408 not covered by the sacrificial gate structures 410 are selectively etched to remove sacrificial layers 404 while the semiconductor layers 402 both outside and under the sacrificial gate structures 410 remain. In some embodiments, a method for removing select portions of, or all of, the stack structures 408 not covered by sacrificial gate structure 410 and removing gate spacer layer 418 may include one or more etching processes, such as one or more anisotropic etching processes. In addition, an etching process can selectively remove sacrificial layers 404 while retaining the semiconductor layers 402. The etching process may be stopped when the top surface of the substrate 400 is exposed, or a top portion of the substrate 400 is removed during the etching process(es).

Referring to FIG. 24 and FIG. 25G, sacrificial layers 404 are laterally recessed from the semiconductor layers 402 and the gate spacers 420. As such, recesses 424 are formed at sidewalls of the remaining portions of the stack structures 408. In some embodiments, the sacrificial layers 404 are laterally recessed from the semiconductor layers 402 and the gate spacers 420 by a distance ranging from 0.5 nm to 1 nm. A method for lateral recessing the sacrificial layers 404 may include an etching process, such as an isotropic etching process. By properly selecting etchants for the etching process and/or by properly selecting the materials of the sacrificial layers 404 and the semiconductor layers 402, the sacrificial layers 404 can be etched without consuming the semiconductor layers 402 and other components in the current structure. Similarly, the structure illustrated in FIG. 25F can subjected to the processing to laterally recess the sacrificial layers 404 under the sacrificial gate structures 410 in the manner shown in FIG. 25G without removing the semiconductor layers 402 that are both covered and not covered by the sacrificial gate structures 410.

Referring to FIG. 24 and FIG. 25H, an insulating material is filled in the recesses 424 at the sidewalls of the stack structures 408. Portions of the insulating material filled in the recesses 424 form inner spacers 428. In some embodiments, exposed surfaces of the inner spacers 328 are substantially coplanar with exposed surfaces of the semiconductor layers 402 and sidewalls of the gate spacers 420. In alternative embodiments, the exposed surfaces of the inner spacers 428 are indented from the exposed surfaces of the semiconductor layers 402 and the sidewalls of the gate spacers 420. A material of the insulating material for forming the inner spacers 328 may include silicon oxide, silicon nitride, silicon carbide, silicon carbide nitride, silicon oxide carbide, silicon carbide oxynitride, or other suitable dielectric materials or combinations thereof. A method for forming the inner spacers 328 may include initially forming a material layer globally covering the structure shown in FIG. 25G, and then removing portions of this blanket layer outside the recesses 424. Remaining portions of insulating material layer form the inner spacers 428. In some embodiments, the material layer is formed by using a deposition process (e.g., a CVD process or an ALD process), and the portions of the material layer are removed by using an etching process (e.g., an anisotropic etching process).

Referring to FIG. 24 and FIG. 25I, process P108 is continued, and source/drain structures 430 are formed on the substrate 400 to form a common active region extending between sacrificial gate structures 410. The sacrificial gate structures 410 are respectively located between source/drain structures 430, and are separated from the source/drain structures 430 by the gate spacers 418. In addition, the semiconductor layers 402 and the inner spacers 428 covered by each sacrificial gate structure 410 are in lateral contact with a pair of the source/drain structures 430. Similarly, the structure illustrated in FIG. 25F be further processed to form the source/drain structures 430 around the semiconductor layers that are not covered by the sacrificial gate structures 410. A material of the source/drain structures 430 may include silicon, silicon germanium, silicon carbide or the like. In some embodiments, the source/drain structures 430 are formed by an epitaxial process. In these embodiments, the source/drain structures 430 may be grown from the semiconductor layers 402 and the exposed portions of the substrate 400. Even though the source/drain structures 430 are depicted as rectangular cuboids, the source/drain structures 430 may be formed as other shapes, the present disclosure is not limited to illustrated shapes of the source/drain structures 430.

Referring to FIG. 24 and FIG. 25J, process P110 is initiated by removing the sacrificial gate structures 410 in some embodiments. A dielectric layer 432 is formed on the source/drain structures 430. In some embodiments, the dielectric layer 432 initially covers the whole structure shown in FIG. 25I, and then a planarization process may be performed to remove a top portion of the dielectric layer 432, and to expose the sacrificial gate structures 410. In certain cases, top portions of the sacrificial gate structures 410 may also be removed during the planarization process. For instance, the planarization process may include a chemical mechanical polishing (CMP) process, an etching process, or a combination thereof. After the sacrificial gate structures 410 are exposed, the remainder portion of the sacrificial gate structures 410 are removed, and cavities respectively defined between adjacent gate spacers 420 are formed. The semiconductor layers 402 and the sacrificial layers 404 previously covered by the sacrificial gate structures 410 are currently exposed in the cavities. A material of the dielectric layer 432 may include tetraethylorthosilicate (TEOS) oxide, un-doped silicate glass, or doped silicon oxide (e.g., borophosphosilicate glass (BPSG), fused silica glass (FSG), phosphosilicate glass (PSG), boron doped silicon glass (BSG)), other suitable dielectric materials or combinations thereof, and a method for forming the dielectric layer 432 may include a deposition process, such as a CVD process. In addition, the sacrificial gate structures 410 may be removed by an etching process, such as an isotropic etching process.

In some embodiments, a contact etching stop layer (CESL) (not shown) is formed on the structure shown in FIG. 25I before forming the dielectric layer 432. Initially, the CESL layer may conformally cover the source/drain structures 430 and the sacrificial gate structures 410. Thereafter, a top portion of the CESL layer covering the sacrificial gate structures 410 may be removed along with the top portion of the dielectric layer 432 during the planarization process. A material of the CESL layer may include silicon nitride, silicon oxynitride, silicon nitride with oxygen or carbon elements, the like or combinations thereof, and a method for forming the CESL layer may include a deposition process, such as a CVD process or an ALD process.

Referring to FIG. 24 and FIG. 25K, process P110 is continued to remove sacrificial layers 404. As such, the semiconductor layers 402 are released in the cavities respectively defined between adjacent gate spacers 420. The released semiconductor layers 402 can function as channel structures. In addition, inner sidewalls of the inner spacers 428 previously covered by the sacrificial layers 404 are currently exposed in the cavities. In some embodiments, a method for removing the sacrificial layers 404 includes an etching process, such as an isotropic etching process. By properly selecting etchants for the etching process and/or properly selecting the materials of the sacrificial layers 404 and the semiconductor layers 402, the sacrificial layers 404 can be etched without removing the semiconductor layers 402 and other components in the current structure.

Referring to FIG. 24, FIG. 25L and FIG. 25M, process P112 of forming gate dielectric layers and process P114 of forming gate lines for transistors 440 are performed in some embodiments. Gate dielectric gate layers 424 and gate lines including gate material 436 are formed in the cavities respectively defined between adjacent gate spacers 420. Previously shown sacrificial gate structures 410 may be regarded as being replaced by the gate structures 438. As shown in FIG. 25L and FIG. 25M, the gate dielectric layers 434 respectively line the exposed surfaces of the semiconductor layers 402, the substrate 400, the inner spacers 428, and the gate spacers 420 in the cavities defined between adjacent gate spacers 420. The gate material 436 of the gate electrodes fills the space in these cavities. A material of the gate dielectric layer 434 may include a high-k dielectric material. Examples of the high-k dielectric material may include HfO₂, HfSiO, HfSiON, HfTaO, HfSiO, HfZrO, zirconium oxide, aluminum oxide, titanium oxide, hafnium dioxide-alumina (HfO₂—Al₂O₃) alloy, other suitable high-k dielectric materials, and/or combinations thereof. A gate material 436 may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In addition, a method for forming the gate dielectric layers 434 may include a deposition process, such as a CVD process or an ALD process. A method for forming gate material 436 of the gate electrodes may include a deposition process (e.g., a CVD process or an ALD process), a plating process (e.g., an electrical plating process or an electroless plating process) or a combination thereof.

In some embodiments, one or more work function layers (such as the work function layer 118 as described with reference to FIG. 13B) is formed between each gate dielectric layer 432 and the overlying gate electrode 436. In addition, in some embodiments, interfacial layers (not shown) are formed on the exposed surfaces of the semiconductor layers 402 before forming the gate dielectric layers 434. The transistors 440 respectively include one of the gate structures 438, the semiconductor layers 402 in this gate structure 438, and a pair of source/drain structures 430 at opposite sides of this gate structure 436.

Referring to FIG. 24 and FIG. 25N, process P112 of forming gate dielectric layers and a process P114 of forming a focused anti-fuse gate line of a focused anti-fuse transistor 442 is performed. Gate dielectric layers 434 are formed in cavities corresponding to transistor 440 and focused anti-fuse transistor 442. A sacrificial material (not shown) is deposited into a cavity corresponding to transistor 440 and then a second dielectric material 444 is deposited into the cavity corresponding to the focused anti-fuse transistor 442. In an embodiment, the second dielectric material 444 is deposited to a specified level in the cavity leaving one or more upper semiconductor layers 402U exposed. In another embodiment, the second dielectric material fills the cavity, and then the structure is masked and photolithographic and etching processes are conducted to form an opening and to remove excess second dielectric material to expose one or more upper semiconductor layers 402. The sacrificial material is removed from the cavity corresponding to the transistor 440 and then the gate material 436 and, optionally work function material, are deposited in the cavity corresponding to the transistor 440 and over the upper semiconductor layers 402U in the cavity corresponding to the focused anti-fuse transistor 442.

Referring to FIG. 24 and FIG. 25O, a process P116 of forming an isolating structure is performed in some embodiments. Gate dielectric layers 434 are formed in cavities corresponding to transistor 440 and an isolating structure to be a plural dielectric sacrificial gate line 444. A sacrificial material (not shown) is deposited into a cavity corresponding to transistor 440 and then a second dielectric material 444 is deposited into the cavity corresponding to the plural dielectric sacrificial gate line 444. The second dielectric material can be deposited to a specified level in the cavity while leaving one or more upper semiconductor layers 402U exposed, or excess dielectric material can be selectively removed to expose one or more upper semiconductor layers 402. A first dielectric material 446 is then deposited the over the upper semiconductor layers 402U in the cavity corresponding to the plural dielectric sacrificial gate line 444. The sacrificial material is removed from the cavity corresponding to the transistor 440 and then the gate material 436 and, optionally work function material, are deposited in the cavity corresponding to the transistor 440.

The first and second dielectric materials can independently include one or more selected from hafnium oxide, zirconium oxide, aluminum oxide, aluminum nitride, titanium nitride, silicon oxide, silicon nitride, silicon oxynitride, silicon oxy-carbo-nitride, or the like. The first and second dielectric materials can be the same or different. In addition, a method for depositing the first and second dielectric materials can be the same or different and may include a deposition process, such as a CVD process or an ALD process.

By implementing isolation regions including any of CPODE and sacrificial gates, the overall cell area of a semiconductor device can be reduced, and the total number of pins, e.g., accounting for word lines, select lines, and bit lines, can be reduced. By implementing a sacrificial gate line and gate lines including focused anti-fuse structures, a breakdown point of an anti-fuse structure can be controlled to improve variation in on-cell current.

According to an embodiment, a method of manufacturing a semiconductor device includes depositing a first stack structure and a second stack structure on a substrate. The first and second stack structures extend in a first direction and include semiconductor layers and sacrificial layers alternately stacked on the substrate. The method further includes depositing a plurality of sacrificial gates on the substrate. The sacrificial gates extend in a second direction crossing the first direction and cover the first and second stack structures. The method further includes replacing portions of the first stack structure between the sacrificial gates with a first active region. The method further includes replacing portions of the second stack structure between the sacrificial gates with a second active region. The method further includes etching the plurality of sacrificial gates and the sacrificial layers that laid under the sacrificial gates to expose channel regions of the first stack structure and channel regions of the second stack structure. The method further includes depositing a gate dielectric material around the semiconductor layers exposed in the channel regions of the first and second stack structures. The method further includes forming a first gate line extending in the second direction, the first gate line intersecting a channel region of the channel regions of the first stack structure and intersecting a channel region of the channel regions of the second stack structure. The method further includes forming a second gate line extending in the second direction, the second gate line intersecting a channel region of the channel regions of the first stack structure and intersecting a channel region of the channel regions of the second stack structure. The method further includes forming a third gate line extending in the second direction between the first and second gate lines and intersecting a channel region of the channel regions of the first stack structure but not intersecting any of the channel regions of the second stack structure. The method further includes forming a fourth gate line extending in the second direction between the third and second gate lines and intersecting a channel region of the channel regions of the first stack structure but not intersecting any of the channel regions of the second stack structure. The method further includes forming a fifth gate line in alignment with the third gate line along the second direction and between the first and second gate lines, the fifth gate line intersecting a channel region of the channel regions of the second stack structure but not intersecting any of the channel regions of the first stack structure. The method further includes forming a sixth gate line in alignment with the fourth gate line along the second direction and between the second and fifth gate lines and intersecting a channel region of the channel regions of the second stack structure but not intersecting any of the channel regions of the first stack structure. The method further includes forming a first isolation structure extending in the second direction between the third and fourth gate lines and between the fifth and sixth gate lines. In an embodiment, the forming the first isolation structure includes forming a trench into the substrate and filling the trench with a dielectric material. In an embodiment, the forming the first isolation structure includes forming a first dielectric material around the semiconductor layers in a channel region of the channel regions of the first stack structure with the gate dielectric material being between the first dielectric material and the semiconductor layers. In an embodiment, the forming the first, second, third, and fourth gate lines includes depositing a gate material around the semiconductor layers in the channel regions that are respectively intersected by the first, second, third, and fourth gate lines, wherein the gate dielectric material between the gate material and the semiconductor layers is configured to function as an anti-fuse structure. In an embodiment, the forming the first isolation structure includes forming a first dielectric material around the semiconductor layers below an upper semiconductor layer in a channel region of the channel regions of the first stack structure intersected by the first isolation structure, and forming a second dielectric layer over the upper semiconductor layer of the channel region intersected by the first isolation structure, the forming the third gate line includes forming the first dielectric material around the semiconductor layers below an upper semiconductor layer of the channel region of the first stack structure intersected by the third gate line, and forming a gate material over the upper semiconductor layer of the channel region of the first stack structure intersected by the third gate line, and the forming the fourth gate line includes forming the first dielectric material around the semiconductor layers below an upper semiconductor layer of the channel region of the first stack structure intersected by the fourth gate line, and forming the gate material over the upper semiconductor layer of the channel region of the first stack structure intersected by the fourth gate line, wherein the gate dielectric material between the gate material and the upper semiconductor layers of the channel regions of the first stack structure intersected by the third and fourth gate lines functions as an anti-fuse structure. In an embodiment, the method further includes forming a seventh gate line extending in the second direction and intersecting a channel region of the channel regions of the first stack structure and a channel region of the channel regions of the second stack structure, and forming an eighth gate line extending in the second direction and intersecting a channel region of the channel regions of the first stack structure and a channel region of the channel regions of the second stack structure, wherein the first and second gate lines are between the seventh and eighth gate lines. In an embodiment, the method further includes forming a second isolating structure extending in the second direction and intersecting the first and second active regions proximal to the first gate line; and forming a third isolating structure extending in the second direction and intersecting the first and second active regions proximal to the second gate line. In an embodiment, the method further includes forming a second isolating structure extending in the second direction and intersecting the first and second active regions proximal to the seventh gate line; and a third isolating structure extending in the second direction and intersecting the first and second active regions proximal to the eighth gate line. In an embodiment, the replacing portions of the first and second stack structures between the sacrificial gates respectively with the first and second active regions includes removing the sacrificial layers from between the sacrificial gates and forming source/drain structures around the semiconductor layers between the sacrificial gates.

According to another embodiment, a method of manufacturing a semiconductor device, the method includes depositing a first stack structure and a second stack structure on a substrate, the first and second stack structures extending in a first direction and including semiconductor layers and sacrificial layers alternately stacked on the substrate. The method further includes depositing a plurality of sacrificial gates on the substrate, the sacrificial gates extending in a second direction crossing the first direction and covering the first and second stack structures. The method further includes replacing portions of the first stack structure between the sacrificial gates with a first active region. The method further includes replacing portions of the second stack structure between the sacrificial gates with a second active region. The method further includes etching the plurality of sacrificial gates and the sacrificial layers that laid under the select sacrificial gates to expose channel regions of the first stack structure and channel regions of the second stack structure. The method further includes depositing a gate dielectric material around the semiconductor layers exposed in the channel regions of the first and second stack structures. The method further includes forming a first gate line extending in the second direction, the first gate line intersecting a channel region of the channel regions of the first stack structure but not intersecting any of the channel regions of the second stack structure. The method further includes forming a second gate line extending in the second direction, the second gate line intersecting a channel region of the channel regions of the first stack structure but not intersecting any of the channel regions of the second stack structure. The method further includes forming a third gate line extending in alignment with the first gate line along the second direction, the third gate line intersecting a channel region of the channel regions of the second stack structure but not intersecting any of the channel regions of the first stack structure. The method further includes forming a fourth gate line extending in alignment with the fourth gate line along the second direction, the fourth gate line intersecting a channel region of the channel regions of the second stack structure but not intersecting any of the channel regions of the first stack structure. The method further includes forming a fifth gate line extending in the second direction, the fifth gate line intersecting a channel region of the channel regions of the first stack structure between the first and second gate lines and intersecting a channel region of the channel regions of the second stack structure between the third and fourth gate lines. The method further includes forming a sixth gate line extending in the second direction, the sixth gate line intersecting a channel region of the channel regions of the first stack structure between the fifth and second gate lines and intersecting a channel region of the channel regions of the second stack structure between the fifth and fourth gate lines. In an embodiment, the forming the first gate line includes forming a first dielectric material around the semiconductor layers below an upper semiconductor layer of the channel region of the first stack structure intersected by the first gate line, and forming a gate material over the upper semiconductor layer of the channel region of the first stack structure intersected by the first gate line, the forming the second gate line includes forming the first dielectric material around the semiconductor layers below an upper semiconductor layer of the channel region of the first stack structure intersected by the second gate line, and forming the gate material over the upper semiconductor layer of the channel region of the first stack structure intersected by the second gate line, the forming the third and the fourth gate line includes forming the gate material around the semiconductor layers the channel regions of the first stack structure that are intersected by the third and fourth gate lines, wherein the gate dielectric material is configured to function as an anti-fuse structure between the upper semiconductor layers of the channel regions intersected by the first and second gate lines and the gate material formed over the upper semiconductor layers of the channel regions intersected by the first and second gate lines. In an embodiment, the channel regions of the first stack structure intersected by the first second, third, and fourth gate structures have two semiconductor layers. In an embodiment, the channel regions of the first stack structure intersected by the first second, third, and fourth gate structures have three semiconductor layers. In an embodiment, the channel regions of the first stack structure intersected by the first second, third, and fourth gate structures have four semiconductor layers.

According to another embodiment, a semiconductor device includes a substrate; an active region disposed over the substrate and extending in a first direction. The device further includes an isolation region disposed over the substrate, the active region protruding above the isolation region. The device further includes a plurality of gate lines extending in a second direction crossing the first direction and intersecting respective channel regions including a stack of semiconductor layers aligned with the active region. At least two gate lines of the plurality of gate lines include a gate material and a dielectric material, the gate material being disposed over an upper semiconductor layer of the channel regions that are intersected by the at least two gate lines, and the dielectric material being below the upper semiconductor layer and between semiconductor layers below the upper semiconductor layer of the channel regions that are intersected by the at least two gate lines. At least one gate line of the plurality of gate lines includes the gate material around the semiconductor layers of a channel region of the channel regions that is intersected by the at least one gate line. The device further includes a gate dielectric layer disposed between the gate material and the upper semiconductor layer of the least two gate lines, the gate dielectric layer being configured to function as an anti-fuse structure. In an embodiment, the semiconductor layers extend in the first direction from the channel regions through the active region, and a source/drain structure surrounds the semiconductor layers in the active region. In an embodiment, the active region includes one of an n-type material or a p-type material and the substrate includes the other of the n-type or the p-type material. In an embodiment, the device further includes a plurality of metal over diffusion lines extending in the second direction and contacting the active region between the gate lines. In an embodiment, the stack of semiconductor layers includes four semiconductor layers. In an embodiment, the active region includes one of an n-type material or a p-type material and the substrate includes the other of the n-type or the p-type material.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
depositing a first stack structure and a second stack structure on a substrate, the first and second stack structures extending in a first direction and comprising semiconductor layers and sacrificial layers alternately stacked on the substrate;
depositing a plurality of sacrificial gates on the substrate, the sacrificial gates extending in a second direction crossing the first direction and covering the first and second stack structures;
replacing portions of the first stack structure between the sacrificial gates with a first active region;
replacing portions of the second stack structure between the sacrificial gates with a second active region;
etching the plurality of sacrificial gates and the sacrificial layers that laid under the sacrificial gates to expose channel regions of the first stack structure and channel regions of the second stack structure;
depositing a gate dielectric material around the semiconductor layers exposed in the channel regions of the first and second stack structures;
forming a first gate line extending in the second direction, the first gate line intersecting a channel region of the channel regions of the first stack structure and intersecting a channel region of the channel regions of the second stack structure;
forming a second gate line extending in the second direction, the second gate line intersecting a channel region of the channel regions of the first stack structure and intersecting a channel region of the channel regions of the second stack structure;
forming a third gate line extending in the second direction between the first and second gate lines and intersecting a channel region of the channel regions of the first stack structure but not intersecting any of the channel regions of the second stack structure;
forming a fourth gate line extending in the second direction between the third and second gate lines and intersecting a channel region of the channel regions of the first stack structure but not intersecting any of the channel regions of the second stack structure;
forming a fifth gate line in alignment with the third gate line along the second direction and between the first and second gate lines, the fifth gate line intersecting a channel region of the channel regions of the second stack structure but not intersecting any of the channel regions of the first stack structure;
forming a sixth gate line in alignment with the fourth gate line along the second direction and between the second and fifth gate lines and intersecting a channel region of the channel regions of the second stack structure but not intersecting any of the channel regions of the first stack structure; and
forming a first isolation structure extending in the second direction between the third and fourth gate lines and between the fifth and sixth gate lines.

2. The method of claim 1, wherein the forming the first isolation structure comprises forming a trench into the substrate and filling the trench with a dielectric material.

3. The method of claim 1, wherein the forming the first isolation structure comprises forming a first dielectric material around the semiconductor layers in a channel region of the channel regions of the first stack structure with the gate dielectric material being between the first dielectric material and the semiconductor layers.

4. The method of claim 3, wherein the forming the first, second, third, and fourth gate lines comprises depositing a gate material around the semiconductor layers in the channel regions that are respectively intersected by the first, second, third, and fourth gate lines, wherein the gate dielectric material between the gate material and the semiconductor layers is configured to function as an anti-fuse structure.

5. The method of claim 1, wherein
the forming the first isolation structure comprises forming a first dielectric material around the semiconductor layers below an upper semiconductor layer in a channel region of the channel regions of the first stack structure intersected by the first isolation structure, and forming a second dielectric layer over the upper semiconductor layer of the channel region intersected by the first isolation structure,
the forming the third gate line comprises forming the first dielectric material around the semiconductor layers below an upper semiconductor layer of the channel region of the first stack structure intersected by the third gate line, and forming a gate material over the upper semiconductor layer of the channel region of the first stack structure intersected by the third gate line, and
the forming the fourth gate line comprises forming the first dielectric material around the semiconductor layers below an upper semiconductor layer of the channel region of the first stack structure intersected by the fourth gate line, and forming the gate material over the upper semiconductor layer of the channel region of the first stack structure intersected by the fourth gate line,
wherein the gate dielectric material between the gate material and the upper semiconductor layers of the channel regions of the first stack structure intersected by the third and fourth gate lines functions as an anti-fuse structure.

6. The method of claim 5, further comprising:
forming a seventh gate line extending in the second direction and intersecting a channel region of the channel regions of the first stack structure and a channel region of the channel regions of the second stack structure, and
forming an eighth gate line extending in the second direction and intersecting a channel region of the channel regions of the first stack structure and a channel region of the channel regions of the second stack structure, wherein the first and second gate lines are between the seventh and eighth gate lines.

7. The method of claim 1, further comprising
forming a second isolating structure extending in the second direction and intersecting the first and second active regions proximal to the first gate line; and
forming a third isolating structure extending in the second direction and intersecting the first and second active regions proximal to the second gate line.

8. The method of claim 5, further comprising
forming a second isolating structure extending in the second direction and intersecting the first and second active regions proximal to the seventh gate line; and
a third isolating structure extending in the second direction and intersecting the first and second active regions proximal to the eighth gate line.

9. The method of claim 1, wherein the replacing portions of the first and second stack structures between the sacrificial gates respectively with the first and second active regions comprises removing the sacrificial layers from between the sacrificial gates and forming source/drain structures around the semiconductor layers between the sacrificial gates.

10. A method of manufacturing a semiconductor device, the method comprising:
depositing a first stack structure and a second stack structure on a substrate, the first and second stack structures extending in a first direction and comprising semiconductor layers and sacrificial layers alternately stacked on the substrate;
depositing a plurality of sacrificial gates on the substrate, the sacrificial gates extending in a second direction crossing the first direction and covering the first and second stack structures;
replacing portions of the first stack structure between the sacrificial gates with a first active region;
replacing portions of the second stack structure between the sacrificial gates with a second active region;
etching the plurality of sacrificial gates and the sacrificial layers that laid under the select sacrificial gates to expose channel regions of the first stack structure and channel regions of the second stack structure;
depositing a gate dielectric material around the semiconductor layers exposed in the channel regions of the first and second stack structures;
forming a first gate line extending in the second direction, the first gate line intersecting a channel region of the channel regions of the first stack structure but not intersecting any of the channel regions of the second stack structure;
forming a second gate line extending in the second direction, the second gate line intersecting a channel region of the channel regions of the first stack structure but not intersecting any of the channel regions of the second stack structure;
forming a third gate line extending in alignment with the first gate line along the second direction, the third gate line intersecting a channel region of the channel regions of the second stack structure but not intersecting any of the channel regions of the first stack structure;
forming a fourth gate line extending in alignment with the fourth gate line along the second direction, the fourth gate line intersecting a channel region of the channel regions of the second stack structure but not intersecting any of the channel regions of the first stack structure;
forming a fifth gate line extending in the second direction, the fifth gate line intersecting a channel region of the channel regions of the first stack structure between the first and second gate lines and intersecting a channel region of the channel regions of the second stack structure between the third and fourth gate lines; and
forming a sixth gate line extending in the second direction, the sixth gate line intersecting a channel region of the channel regions of the first stack structure between the fifth and second gate lines and intersecting a channel region of the channel regions of the second stack structure between the fifth and fourth gate lines.

11. The method of claim 10, wherein
the forming the first gate line comprises forming a first dielectric material around the semiconductor layers below an upper semiconductor layer of the channel region of the first stack structure intersected by the first gate line, and forming a gate material over the upper semiconductor layer of the channel region of the first stack structure intersected by the first gate line,
the forming the second gate line comprises forming the first dielectric material around the semiconductor layers below an upper semiconductor layer of the channel region of the first stack structure intersected by the second gate line, and forming the gate material over the upper semiconductor layer of the channel region of the first stack structure intersected by the second gate line,
the forming the third and the fourth gate line comprises forming the gate material around the semiconductor layers the channel regions of the first stack structure that are intersected by the third and fourth gate lines,
wherein the gate dielectric material is configured to function as an anti-fuse structure between the upper semiconductor layers of the channel regions intersected by the first and second gate lines and the gate material formed over the upper semiconductor layers of the channel regions intersected by the first and second gate lines.

12. The method of claim 11, wherein the channel regions of the first stack structure intersected by the first second, third, and fourth gate structures have two semiconductor layers.

13. The method of claim 11, wherein the channel regions of the first stack structure intersected by the first second, third, and fourth gate structures have three semiconductor layers.

14. The method of claim 11, wherein the channel regions of the first stack structure intersected by the first second, third, and fourth gate structures have four semiconductor layers.

15. A semiconductor device comprising:
a substrate;
an active region disposed over the substrate and extending in a first direction;
an isolation region disposed over the substrate, the active region protruding above the isolation region;
a plurality of gate lines extending in a second direction crossing the first direction and intersecting respective channel regions comprising a stack of semiconductor layers aligned with the active region;
at least two gate lines of the plurality of gate lines comprise a gate material and a dielectric material, the gate material being disposed over an upper semiconductor layer of the channel regions that are intersected by the at least two gate lines, and the dielectric material being below the upper semiconductor layer and between semiconductor layers below the upper semiconductor layer of the channel regions that are intersected by the at least two gate lines;
at least one gate line of the plurality of gate lines comprising the gate material around the semiconductor layers of a channel region of the channel regions that is intersected by the at least one gate line; and
a gate dielectric layer disposed between the gate material and the upper semiconductor layer of the least two gate lines, the gate dielectric layer being configured to function as an anti-fuse structure.

16. The semiconductor device of claim 15, wherein the semiconductor layers extend in the first direction from the channel regions through the active region, and a source/drain structure surrounds the semiconductor layers in the active region.

17. The semiconductor device of claim 15, wherein the active region comprises one of an n-type material or a p-type material and the substrate comprises the other of the n-type or the p-type material.

18. The semiconductor device of claim 15, further comprising a plurality of metal over diffusion lines extending in the second direction and contacting the active region between the gate lines.

19. The semiconductor device of claim 15, wherein the stack of semiconductor layers comprises four semiconductor layers.

20. The semiconductor device of claim 15, wherein the active region comprises one of an n-type material or a p-type material and the substrate comprises the other of the n-type or the p-type material.
